(19) United States
(12) Patent Application Publication
(10) Pub. No.: US 2023/0371409 A1
(43) Pub. Date: Nov. 16, 2023

(54) Resistive Change Elements Using Nanotube Fabrics Employing Break-Type Switching Sites

(71) Applicant: Nantero, Inc., Woburn, MA (US)

(72) Inventor: Thomas Rueckes, Rockport, MA (US)

(73) Assignee: Nantero, Inc., Woburn, MA (US)

(21) Appl. No.: 18/196,044

(22) Filed: May 11, 2023

Related U.S. Application Data
(60) Provisional application No. 63/341,478, filed on May 13, 2022.

(51) Int. Cl. H10N 70/00; H10B 63/00

(52) U.S. Cl. CPC H10N 70/8845; H10N 70/826; H10B 63/84; B82Y 30/00

(57) ABSTRACT

Two-terminal nanotube switching devices employing nanotube fabrics configured with breaks among the nanotube elements and methods of making such devices are disclosed. Breaks within the nanotube elements can be formed by applying a sufficiently high voltage or a sufficiently high electrical current through the nanotube fabric. These breaks within the individual nanotube elements realize switching sites within the fabric which provide uniform and controllable characteristics for the nanotube switching device.

### CROSS-REFERENCE TO RELATED APPLICATIONS

This application is related to the following U.S. patents, which are assigned to the assignee of the present application, and are hereby incorporated by reference in their entirety:
Methods of Nanotube Films and Articles (U.S. Pat. No. 6,835,591), filed Apr. 23, 2002;
Spin-Coatable Liquid for Formation of High Purity Nanotube Films (U.S. Pat. No. 7,375,369), filed Jun. 3, 2004;
High Purity Nanotube Fabrics and Films (U.S. Pat. No. 7,858,185), filed Jun. 3, 2004;
Resistive Elements Using Carbon Nanotubes (U.S. Pat. No. 7,365,632), filed Sep. 20, 2005;
Two-Terminal Nanotube Devices and Systems and Methods of Making Same (U.S. Pat. No. 7,781,862), filed Nov. 15, 2005;
Aqueous Carbon Nanotube Applicator Liquids and Methods for Producing Applicator Liquids Thereof (U.S. Pat. No. 7,666,382), filed Dec. 15, 2005;
Memory Elements and Cross Point Switches and Arrays of Same Using Nonvolatile Nanotube Blocks (U.S. Pat. No. 7,835,170), filed Aug. 8, 2007;
Nonvolatile Nanotube Diodes and Nonvolatile Nanotube Blocks and Systems using Same and Methods of Making Same (U.S. Pat. No. 8,217,490), filed Aug. 8, 2007; and
Methods for Controlling Density, Porosity, and/or Gap Size Within Nanotube Fabric Layers and Films (U.S. Pat. No. 9,617,151), filed Oct. 31, 2021.

This application is related to the following patent applications, which are assigned to the assignee of the present application, and are hereby incorporated by reference in their entirety:
Combinational Resistive Change Elements (U.S. patent application Ser. No. 16/434,813, now published as US 2020/0388331), filed Jun. 7, 2019; and
Three-Dimensional Array Architecture for Resistive Change Element Arrays and Methods of Making Same (U.S. patent application Ser. No. 16/908,277, now published as US 2021-0399219), filed Jun. 22, 2020.

### TECHNICAL FIELD

The present disclosure relates generally to resistive change elements using nanotube fabrics and, more specifically, to the nanotube fabrics within such resistive change elements which include break-type switching sites.

### BACKGROUND

Any discussion of the related art throughout this specification should in no way be considered as an admission that such art is widely known or forms part of the common general knowledge in the field.

Nanotube fabric layers and films are used in a plurality of electronic structures, and devices. For example, U.S. Pat. No. 8,217,490 to Bertin et al., incorporated herein by reference in its entirety, teaches methods of using nanotube fabric layers to realize nonvolatile devices such as, but not limited to, block switches, programmable resistive elements, and programmable logic devices. U.S. Pat. No. 7,365,632 to Bertin et al., incorporated herein by reference, teaches the use of such fabric layers and films within the fabrication of thin film nanotube based resistors. U.S. Pat. No. 7,927,992 to Ward et al., incorporated herein by reference in its entirety, teaches the use of such nanotube fabrics and films to form heat transfer elements within electronic devices and systems.

Through a variety of previously known techniques (described in more detail within the incorporated references) nanotube elements can be rendered conducting, non-conducting, or semi-conducting before or after the formation of a nanotube fabric layer or film, allowing such nanotube fabric layers and films to serve a plurality of functions within an electronic device or system. Further, in some cases the electrical conductivity of a nanotube fabric layer or film can be adjusted between two or more non-volatile states as taught in U.S. Pat. No. 7,781,862 to Bertin et al., incorporated herein by reference in its entirety, allowing for such nanotube fabric layers and films to be used as memory or logic elements within an electronic system.

U.S. Pat. No. 7,335,395 to Ward et al., incorporated herein by reference in its entirety, teaches a plurality of methods for forming nanotube fabric layers and films on a substrate element using preformed nanotubes. The methods include, but are not limited to, spin coating (wherein a solution of nanotubes is deposited on a substrate which is then spun to evenly distribute the solution across the surface of the substrate), spray coating (wherein a plurality of nanotubes are suspended within an aerosol solution which is then dispersed over a substrate), and dip coating (wherein a plurality of nanotubes are suspended in a solution and a substrate element is lowered into the solution and then removed). Further, U.S. Pat. No. 7,375,369 to Sen et al., incorporated herein by reference in its entirety, and U.S. Pat. No. 7,666,382 to Ghenciu et al., incorporated herein by reference in its entirety, teach nanotube solutions well suited for forming a nanotube fabric layer over a substrate element via a spin coating process.

### SUMMARY

The current disclosure relates to resistive change elements using nanotube fabrics which include break-type switching sites, and methods for forming same.

In particular, the present disclosure provides a method of forming a two-terminal resistive change element. This method comprises first depositing a nanotube fabric over a substrate, this nanotube fabric having a first sidewall and a second sidewall and comprising a plurality of nanotubes. This method further comprises forming a first conductive terminal in electrical communication with the first sidewall of the nanotube fabric. This method further comprises forming a second conductive terminal in electrical communication with the second sidewall of the nanotube fabric such that the nanotube fabric provides a conductive path between the first conductive terminal and the second conductive terminal. Finally, the method further comprises applying an electrical stimulus across the first conductive terminal and the second conductive terminal sufficient to create a least one break in at least one of the plurality of nanotubes and wherein this at least one break creates a switching site within the nanotube fabric.

According to one aspect of the present disclosure, substantially all of the nanotube elements within the nanotube fabric have lengths approximately equal to the distance between the first sidewall and the second sidewall.

Under another aspect of the present disclosure, substantially all of the nanotube elements within the nanotube fabric have lengths less than the distance between the first sidewall and the second sidewall.

Under another aspect of the present disclosure, applying the electrical stimulus creates a plurality of breaks in the plurality of nanotubes, and this plurality of breaks provides a plurality of adjustable switching sites across the nanotube fabric.

Under another aspect of the present disclosure, the two-terminal nanotube switching device is rendered into a nonvolatile low resistive SET state by adjusting a plurality of the switching sites into nonvolatile low resistive states and rendered into a nonvolatile high resistive RESET state by adjusting a plurality of the switching sites into nonvolatile high resistive states.

Under another aspect of the present disclosure, the nanotubes are carbon nanotubes.

The present disclosure also provides a two-terminal resistive change element. The element comprises a nanotube fabric having a first sidewall and a second sidewall and comprises a plurality of nanotubes. The element further comprises a first conductive terminal in electrical communication with the first sidewall of the nanotube fabric. The element further comprises a second conductive terminal in electrical communication with the second sidewall of the nanotube fabric such that the nanotube fabric provides a conductive path between the first conductive terminal and the second conductive terminal. The element further comprises a plurality of breaks within the plurality of nanotubes, each break providing a switching site within the nanotube fabric. Within the element, these switching sites are adjustable between a nonvolatile low resistive state and a nonvolatile high resistive state responsive to a programming stimulus applied across the first conductive terminal and the second conductive terminal. Also within the element, the low resistive states and the high resistive states are substantially uniform among the plurality of switching sites.

Other features and advantages of the present disclosure will become apparent from the following description, which is provided below in relation to the accompanying drawings.

### BRIEF DESCRIPTION OF THE DRAWINGS

FIG. 1A is a diagram illustrating a vertically oriented two-terminal nanotube switching device comprising a nanotube fabric layer and using top and bottom contacts.

FIG. 1B is a diagram illustrating a horizontally oriented two-terminal nanotube switching device comprising a nanotube fabric layer and two bottom contacts.

FIG. 1C is a diagram illustrating a horizontally oriented two-terminal nanotube switching device comprising a nanotube fabric layer and using sidewall contacts.

FIG. 2A is a diagram illustrating a device cell comprising a vertically oriented two-terminal nanotube switching device, as depicted in FIG. 1A, and a FET selection device.

FIG. 2B is a diagram illustrating a device cell comprising a horizontally oriented two-terminal nanotube switching device, as depicted in FIG. 1B, and a FET selection device.

FIG. 2C is a diagram illustrating an array of horizontally oriented two-terminal nanotube switching devices with sidewall contacts, as depicted in FIG. 1C.

FIG. 3 is a SEM image of a nanotube fabric.

FIG. 4A is a diagram schematically illustrating the conductive pathways within a nanotube fabric when the nanotube fabric is in a low resistive SET state.

FIG. 4B is a diagram schematically illustrating the conductive pathways within a nanotube fabric when the nanotube fabric is in a high resistive RESET state.

FIG. 5 is a diagram highlighting different types of nanotube-to-nanotube interfaces within a nanotube switching element.

FIG. 6A is a diagram detailing the interface between a first pair of nanotubes interacting sidewall-to-sidewall.

FIG. 6B is a diagram detailing the interface between a second pair of nanotubes interacting sidewall-to-sidewall.

FIG. 6C is a diagram detailing the interface between a third pair of nanotubes interacting end-to-end.

FIG. 7 is a graph plotting the electrical current through different nanotube interfaces as a function of the separation distance between the nanotubes within an atomistic density-functional theory (DFT) simulation.

FIG. 8 is a diagram illustrating creating a break within a single nanotube element to create a switching site according to the methods of the present disclosure.

FIG. 9 is a process diagram illustrating a first method of forming a nanotube switching device according to the methods of the present disclosure which uses relatively long nanotube elements and results in breaks distributed across a nanotube fabric.

FIG. 10 is a process diagram illustrating a second method of forming a nanotube switching device according to the methods of the present disclosure which uses relatively short nanotube elements and results in breaks distributed across a nanotube fabric.

FIG. 11 is a process diagram illustrating a third method of forming a nanotube switching device according to the methods of the present disclosure which uses relatively long nanotube elements and results in breaks located largely within a single region within a nanotube fabric.

FIG. 12 is a process diagram illustrating a fourth method of forming a nanotube switching device according to the methods of the present disclosure which uses a mixture of short and long nanotube elements and results in breaks distributed across a nanotube fabric.

FIG. 13 is a process diagram illustrating a fifth method of forming a nanotube switching device according to the methods of the present disclosure which realizes a vertically oriented two-terminal nanotube switching device which includes break-type switching sites within its nanotube fabric.

FIG. 14 is a process diagram illustrating a sixth method of forming a nanotube switching device according to the methods of the present disclosure which realizes a horizontally oriented two-terminal nanotube switching device with contacts situated below a nanotube fabric and which includes break-type switching sites within its nanotube fabric.

FIG. 15 is a process diagram illustrating a seventh method of forming a nanotube switching device according to the methods of the present disclosure which realizes a horizontally oriented two-terminal nanotube switching device with contacts situated below a nanotube fabric and which uses a mixture of short and long nanotube elements and includes break-type switching sites within its nanotube fabric.

### DETAILED DESCRIPTION

The present disclosure teaches methods for forming two-terminal nanotube switching devices that exhibit low switching energy and narrow resistance value distributions with respect to SET and RESET resistance values across a plurality of switching devices. Such attributes are highly valuable in, for example, large arrays of two-terminal nanotube switching elements. When such arrays are formed using two-terminal nanotube switching devices according to the methods of the present disclosure, they will exhibit highly desirable switching characteristics across the array cells. In certain applications, such desirable switching characteristics may include relatively low switching voltages, uniform switching voltages (as compared cell-to-cell), and tight distributions of resistance values in both SET and RESET state (again, as compared cell-to-cell across the array).

As will be discussed in greater detail below, two-terminal nanotube switching elements employ a nanotube fabric which is adjustable among a plurality of nonvolatile resistive states responsive to a programming voltage or current applied to the fabric. These nanotube fabrics comprise a network of conductive pathways from one nanotube to the next through the fabric. The aggregate of these conductive pathways provides an overall electrical resistance value for the fabric (for example, when measured from one sidewall of the nanotube fabric to another sidewall, or from the top of the nanotube fabric to the bottom). As described in detail below, this electrical resistance value can be adjusted between multiple nonvolatile states responsive to electrical stimuli driven across or through the fabric. For example, a nanotube fabric can initially possess a relatively high electrical resistance (e.g., on the order of 1 Megaohm) and then be rendered into a relatively low resistive state (e.g., on the order of 100 kilohms) by driving a programming current through the nanotube fabric. The nanotube fabric will then remain in the low resistive state indefinity until the application of a second electrical stimulus returns the nanotube fabric to its initial high resistive state.

Without wishing to be bound by theory, it is presented that in certain applications this electrical resistance property of nanotube fabrics is adjusted by activating and deactivating different switching sites throughout the nanotube fabric. Within certain embodiments, these switching sites are located at the physical interface points between individual nanotube elements within the nanotube fabric, at defects in the individual nanotube elements, or at the site of an ion implant within an individual nanotube element. According to the methods of the present disclosure, these switching sites can be controllably introduced into a nanotube fabric by introducing breaks within the individual nanotube elements. These breakpoints in the nanotube elements act as switching sites (electrically analogous to an end-to-end interface between two different nanotube elements) and can be adjusted to modulate a conductive path through the affected nanotube element between a nonvolatile high resistive state and a nonvolatile low resistive state responsive to an applied programming voltage across the nanotube, which alternatively partially repairs the break or reopens it. By using the methods of the present disclosure to control the presence and distribution of these breaks across a nanotube fabric, large arrays of nanotube switching devices using such nanotube fabrics can be realized that exhibit low switching voltages and substantially consistent and predictable SET and RESET resistance values.

Within the present disclosure, the term “nanotube formulation” is used to describe nanotube application solutions—that is a plurality of nanotube elements suspended within a liquid medium capable of being deposited to form a nanotube fabric—with a selected set of parameters. Such parameters can include, but are not limited to, the type of nanotube or nanotubes used within the application solution, the nanotube wall type (e.g., single walled, double walled, or multi-walled), the type and degree of functionalization (or lack thereof) of the nanotube elements, the lengths and length distribution of the nanotube elements, the degree to which the nanotube elements are straight or kinked, the density of the nanotube elements within solution, the purity of the application solution (e.g., level of metallic impurities), the chirality of the nanotube elements, and the liquid medium used.

A fabric of nanotubes as referred to herein for the present disclosure includes a layer of multiple, interconnected carbon nanotubes. A fabric of nanotubes (or nanofabric), in the present disclosure, e.g., a non-woven carbon nanotube (CNT) fabric, may, for example, have a structure of multiple entangled nanotubes that are irregularly arranged relative to one another. Alternatively, or in addition, for example, the fabric of nanotubes for the present disclosure may possess some degree of positional regularity of the nanotubes, e.g., some degree of parallelism along their long axes. Such positional regularity may be found, for example, on a relatively small scale wherein flat arrays of nanotubes are arranged together along their long axes in rafts on the order of one nanotube long and ten to twenty nanotubes wide. In other examples, such positional regularity may be found on a larger scale, with regions of ordered nanotubes, in some cases, extended over substantially the entire fabric layer.

The fabrics of nanotubes retain desirable physical properties of the nanotubes from which they are formed. For example, in some electrical applications, the fabric preferably has a sufficient amount of nanotubes in contact so that at least one ohmic (metallic) or semi-conductive pathway exists from a given point within the fabric to another point within the fabric. Single walled nanotubes may typically have a diameter of about 1-3 nm, and multi walled nanotubes may typically have a diameter of about 3-30 nm. Nanotubes may have lengths ranging from about 0.2 microns to about 200 microns, for example. The nanotubes may curve and occasionally cross one another. Gaps in the fabric, i.e., between nanotubes either laterally or vertically, may exist. Such fabrics may include single-walled nanotubes, multi-walled nanotubes, or both.

The fabric may have small areas of discontinuity with no tubes present. The fabric may be prepared as a layer or as multiple fabric layers, one formed over another. The thickness of the fabric can be chosen as thin as substantially a monolayer of nanotubes or can be chosen much thicker, e.g., tens of nanometers to hundreds of microns in thickness. The porosity of the fabrics can vary from low density fabrics with high porosity to high density fabrics with low porosity. Such fabrics can be prepared by growing nanotubes using chemical vapor deposition (CVD) processes in conjunction with various catalysts, for example.

Other methods for generating such fabrics may involve using spin-coating techniques and spray-coating techniques with preformed nanotubes suspended in a suitable solvent, silk screen printing, gravure printing, and electrostatic spray coating. Nanoparticles of other materials can be mixed with suspensions of nanotubes in such solvents and deposited by spin coating and spray coating to form fabrics with nanoparticles dispersed among the nanotubes.

As described within U.S. Pat. No. 7,375,369 to Sen et al. and U.S. Pat. No. 7,666,382 to Ghenciu et al., both incorporated herein by reference in their entirety, nanotube fabrics and films can be formed by applying a nanotube application solution (for example, but not limited to, a plurality of nanotube elements suspended within an aqueous solution) over a substrate element. A spin coating process, for example, can be used to evenly distribute the nanotube elements over the substrate element, creating a substantially uniform layer of nanotube elements. In other cases, other processes (such as, but not limited to, spray coating processes, dip coating processes, silk screen printing processes, and gravure printing processes) can be used to apply and distribute the nanotube elements over the substrate element.

Further, U.S. Pat. No. 9,617,151 to Sen et al., incorporated herein by reference in its entirety, teaches methods of adjusting certain parameters (for example, the nanotube density or the concentrations of certain ionic species) within nanotube application solutions to either promote or discourage rafting—that is, the tendency for nanotube elements to group together along their sidewalls and form dense, raft-like structures—within a nanotube fabric layer formed with such a solution. By increasing the incidence of rafting within nanotube fabric layers, the density of such fabric layers can be increased, reducing both the number and size of voids and gaps within such fabric layers.

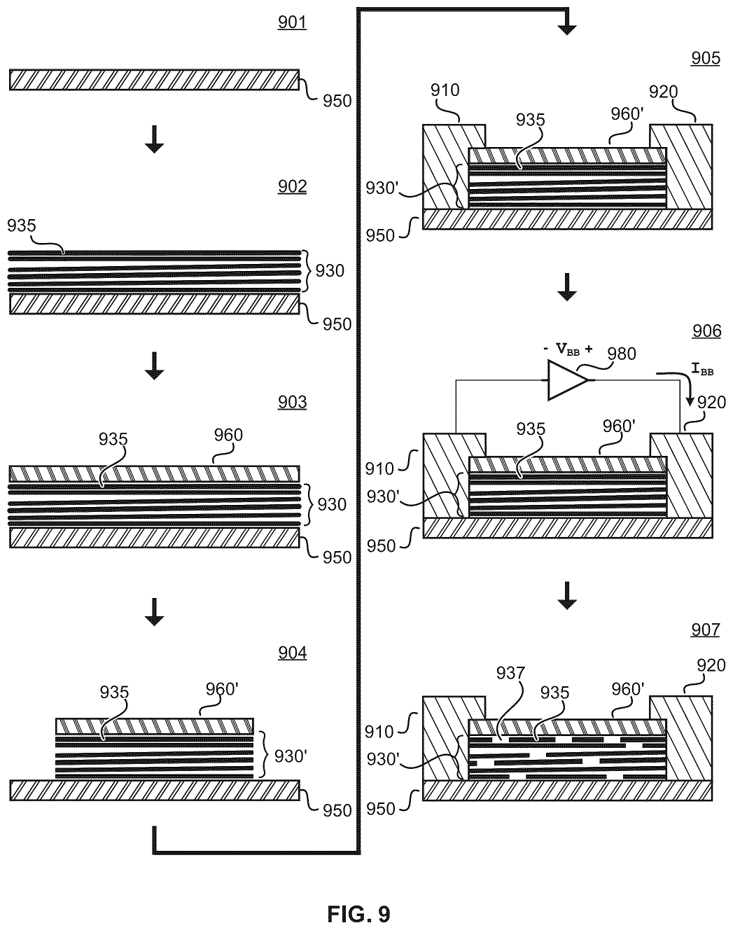

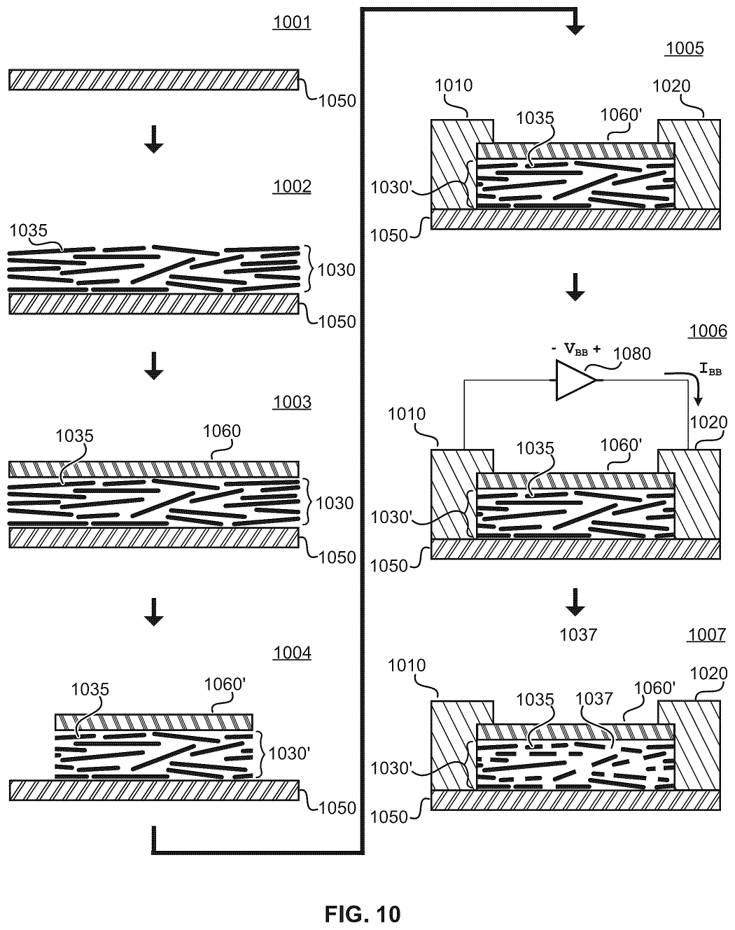

It should be noted that within the present disclosure the term “sidewall” is used two different ways. With respect to individual nanotube elements (for example, elements 935 in FIG. 9 and elements 1035 in FIG. 10), a nanotube sidewall refers to the side-surface of the nanotube elements, running the length of the high-aspect ratio structure. In this way, a nanotube sidewall is distinguished from a nanotube endpoint within the methods of the present disclosure. However, the present disclosure also refers to the sidewall of a nanotube fabric. A nanotube fabric sidewall, as the term is used herein, refers to the side surface of an entire nanotube fabric, such as is formed after an etching operation (for example, the edges on the left and right of etched nanotube fabrics 930′ and 1030′ in FIGS. 9 and 10).

It should also be noted that nanotube elements used and referenced within the embodiments of the present disclosure may be single-walled nanotubes, multi-walled nanotubes, or mixtures thereof and may be of varying lengths. Further, the nanotubes may be conductive, semiconductive, or combinations thereof. Further, the nanotubes may be functionalized (for example, by oxidation with nitric acid resulting in alcohol, aldehydic, ketonic, or carboxylic moieties attached to the nanotubes), or they may be non-functionalized.

Carbon nanotube (CNT) raw materials normally come in dry powder form. In order to integrate the manufacturing of nanotube devices with existing semiconductor facilities, it is often necessary to prepare a spin- or spray-coatable nanotube solution or dispersion before use. Accordingly, the nanotube powder has to be suspended, dispersed, solvated, or mixed in a liquid medium or solvent, so as to form a nanotube solution or dispersion. In some cases, this liquid medium could be water (including, but not limited to, distilled water or deionized water). In other cases, this liquid medium could be a non-aqueous solvent. The nanotube solution formed directly from CNT raw materials may be referred to as a “pristine” nanotube solution. In this disclosure, the term “nanotube solution,” “nanotube suspension,” and “nanotube dispersion” may be used interchangeably to refer to the same thing. The nanotube solution may be an aqueous or non-aqueous solution, and the solvent may be water or an organic/inorganic liquid. In one embodiment, the nanotube solution is an aqueous solution and the solvent is water.

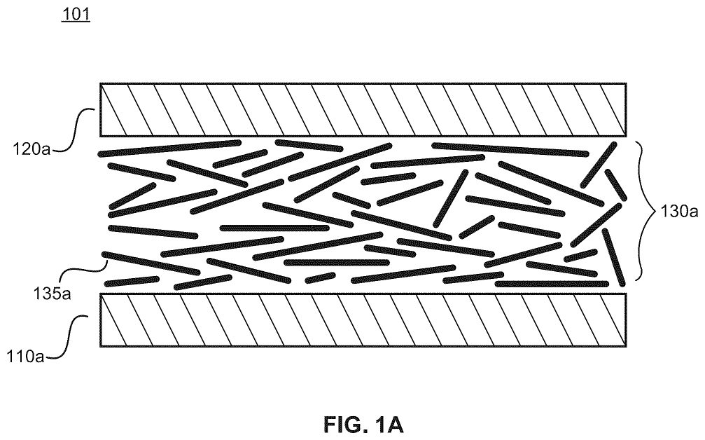

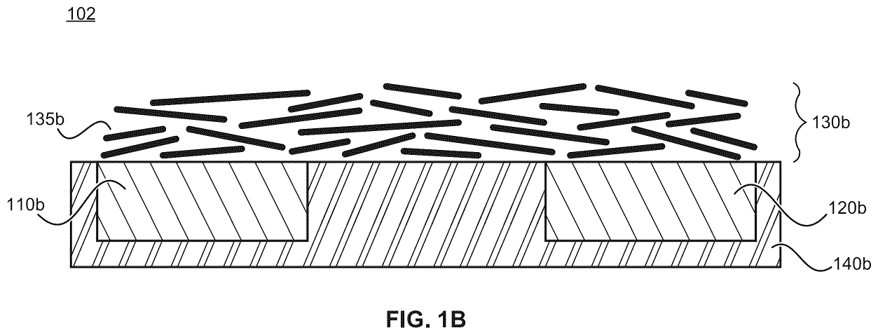

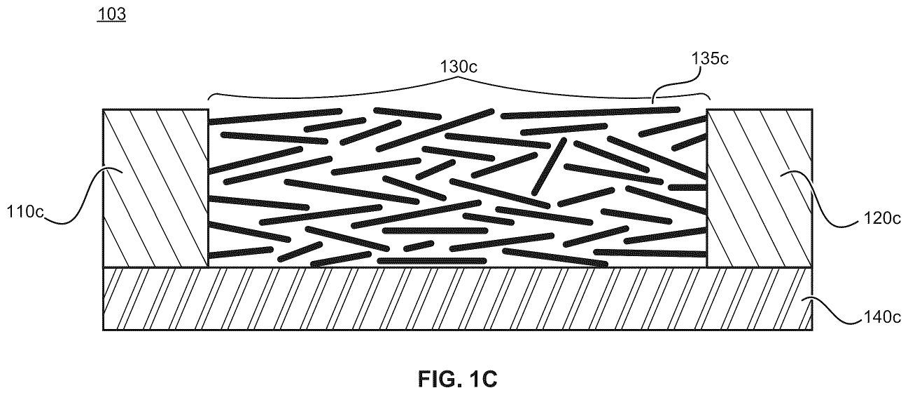

As discussed above, one important use of nanotube fabrics is two-terminal resistive change elements (as depicted, for example, in FIGS. 1A, 1B, and 1C). For example, U.S. Pat. No. 7,781,862 to Bertin et al., incorporated herein by reference in its entirety, discloses a two-terminal nanotube switching device comprising a first and second conductive terminals and a nanotube fabric article. Bertin teaches methods for adjusting the resistivity of the nanotube fabric article between a plurality of nonvolatile resistive states. In at least one embodiment, electrical stimulus is applied to at least one of the first and second conductive elements such as to pass an electric current through the nanotube fabric layer. By carefully controlling this electrical stimulus within a certain set of predetermined parameters (as described by Bertin in U.S. Pat. No. 7,781,862) the resistivity of the nanotube article can be repeatedly switched between a relatively high resistive state and relatively low resistive state. In certain embodiments, these high and low resistive states can be used to store a digital bit of data (that is, a logic ‘1’ or a logic ‘0’), and the two-terminal nanotube switching element used as a memory cell.

Further, U.S. Pat. No. 8,217,490, hereby incorporated by reference in its entirety, also teach non-volatile two-terminal nanotube switches comprising nanotube fabric layers. As described in those patents, responsive to electrical stimuli a nanotube fabric layer can be adjusted or switched among a plurality of non-volatile resistive states, and these non-volatile resistive states can be used to reference informational (logic) states. In this way, resistive change elements (and arrays thereof) are well suited for use as non-volatile memory devices for storing digital data (storing logic values as resistive states) within electronic devices (such as, but not limited to, cell phones, digital cameras, solid state hard drives, and computers). However, the use of resistive change elements is not limited to memory applications. Indeed, arrays of resistive change elements, including the two-terminal resistive change elements taught by the present disclosure, could also be used within logic devices or within analog circuitry.

FIGS. 1A, 1B, and 1C illustrate three different configurations of two-terminal nanotube switching devices (101, 102, and 103). Referring now to FIG. 1A, an exemplary vertical two-terminal nanotube switching device 101 is shown, which uses a bottom conductive terminal 110a and a top conductive terminal 120a. A nanotube fabric 130a comprised of a plurality of individual nanotube elements 135a is disposed between these two conductive terminals (110a and 120a) and provides a conductive path between them which is adjustable among a plurality of nonvolatile resistive states. Within such a vertically oriented device, electrical current flows vertically up or down through nanotube fabric 130a, generally orthogonal to the orientation of the nanotube fabric. Such devices are taught in the incorporated references, including U.S. Pat. No. 7,835,170 to Bertin et al., herein incorporated by reference in its entirety.

Looking now to FIG. 1B, an exemplary horizontal two-terminal nanotube switching device 102 is shown using a first bottom conductive terminal 110b and a second bottom conductive terminal 120b, which are formed within substrate layer 140b. A nanotube fabric 130b comprised of a plurality of individual nanotube elements 135b is disposed over these two conductive terminals (110b and 120b) and provides a conductive path between them which is adjustable among a plurality of nonvolatile resistive states. Within such a horizontally oriented device, electrical current flows horizontally through the nanotube fabric, generally parallel to the orientation of the nanotube fabric. Such devices are taught in the incorporated references, including U.S. Pat. No. 7,781,862 to Bertin et al., herein incorporated by reference in its entirety. It should be noted that while FIG. 1B illustrates a two-terminal nanotube switching device configuration with contacts (110b and 120b) located below nanotube fabric 130b, a similar structure can be realized by first forming a nanotube fabric over the substrate layer and then forming two top contacts above the nanotube fabric. Such a structure is also taught in U.S. Pat. No. 7,781,862.

Looking now to FIG. 1C, an exemplary horizontal two-terminal nanotube switching device 103 is shown using a first sidewall conductive terminal 110c and a second sidewall conductive terminal 120c. For such a device, a nanotube fabric comprised of a plurality of individual nanotube elements 135c is typically first formed over a substrate layer 140c, then etched to provide a nanotube fabric block 130c with desired geometric dimensions. Next, a first sidewall contact 110c and a second sidewall contact 120c are then formed in contact with each side of the nanotube fabric block 130c as shown in FIG. 1C. In this way, nanotube fabric block 130c provides a conductive path between the sidewall contacts (110c and 120c), which is adjustable among a plurality of nonvolatile resistive states. Within such a horizontally oriented device, electrical current flows horizontally through the nanotube fabric, generally parallel to the orientation of the nanotube fabric. Such devices are taught in the incorporated references, including U.S. Patent Publication No. 2021/0399219 to Luan et al., herein incorporated by reference in its entirety.

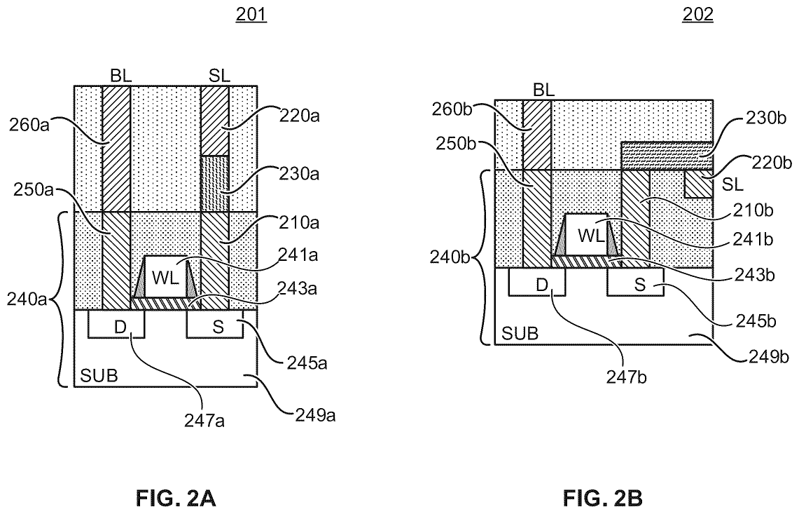

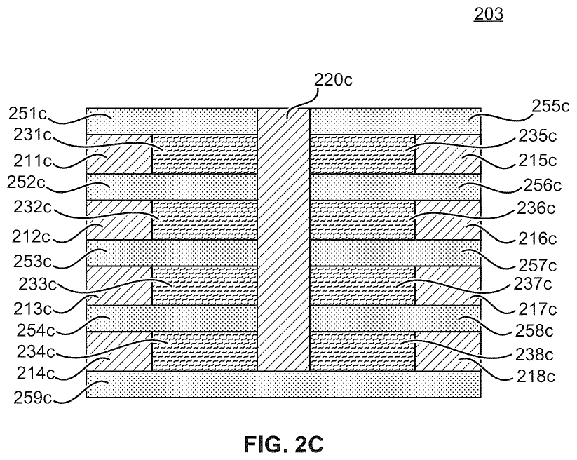

FIGS. 2A and 2B illustrate array cells, each of which employs one of the two-terminal nanotube switching device configurations depicted in FIGS. 1A and 1B, respectively.

FIG. 2A is a diagram depicting the layout of an exemplary resistive change memory cell 201 which includes a vertically oriented two-terminal nanotube switching device analogous to the structure depicted in FIG. 1A. A typical FET device 240a is formed within a first device layer, including a drain 247a and a source 245a formed in substrate layer 249a and a gate structure 241a formed over a gate insulator 243a. The structure and fabrication of such a FET device 240a will be well known to those skilled in the art.

A nanotube fabric element 230a (analogous to nanotube fabric 130a in FIG. 1A) is formed in a second device layer. Conductive structure 210a (analogous to bottom conductive terminal 110a in FIG. 1A) electrically couples the bottom surface of nanotube fabric element 230a with the source terminal 245a of FET device 240a. Conductive structure 220a(analogous to top conductive terminal 120a in FIG. 1A) electrically couples the top surface of nanotube fabric element 230a with an external source line (labeled SL within FIG. 2A) outside the memory cell. Conductive structures 250a and 260a electrically couple the drain terminal 247a of FET device 240a with an external bit line (labeled BL within FIG. 2A). An external word line (labeled WL within FIG. 2A) is electrically coupled to gate structure 241a. Responsive to electrical stimuli applied to the word line, bit line, and source line, array cell 201 can be selected by enabling FET device 240a in order to apply programming stimuli across nanotube fabric 230a.

Looking now to FIG. 2B, a second exemplary array cell 202 is illustrated in a layout diagram. Array cell 202 includes a horizontally oriented two-terminal nanotube switching device with two bottom contacts analogous to the structure depicted in FIG. 1B. As with the array cell 201 detailed in FIG. 2A, a typical FET device 240b is formed within a first device layer, including a drain 247b and a source 245b formed in substrate layer 249b and a gate structure 241b formed over a gate insulator 243b. Again, the structure and fabrication of such an FET device 240b will be well known to those skilled in the art.

A nanotube fabric layer 230b (analogous to nanotube fabric 130b in FIG. 1B) is formed in a second device layer. Conductive structure 210b (analogous to first bottom conductive terminal 110b in FIG. 1B) electrically couples a first end of nanotube fabric element 230b with the source terminal 245b of FET device 240b. Conductive structure 220b (analogous to second bottom conductive terminal 120b in FIG. 1B) electrically couples a second end of nanotube fabric element 230b with an external source line (labeled SL within FIG. 2B) outside the memory cell. Conductive structures 250b and 260b electrically couple the drain terminal 247b of FET device 240b with an external bit line (labeled BL within FIG. 2B). An external word line (labeled WL within FIG. 2B) is electrically coupled to gate structure 241b. Responsive to electrical stimuli applied to the word line, bit line, and source line, array cell 202 can be selected by enabling FET device 240b in order to apply programming stimuli across nanotube fabric layer 230b.

Looking now to FIG. 2C, a three dimensional cross-point array 203 of eight two-terminal nanotube switching devices is shown. The array 203 uses two-terminal nanotube switching devices with sidewall contacts, analogous to the structure shown in FIG. 1C and discussed in detail above. Methods of forming such three-dimensional cross point arrays are described in U.S. Patent Publication No. 2021/0399219 (discussed with respect to FIG. 1C above). The entire array 203 is formed over a base insulating layer 259c. Nanotube fabric elements 231c, 232c, 233c, 234c, 235c, 236c, 237c, and 238c (all analogous to nanotube fabric 130c in FIG. 1C) and first sidewall conductive terminals 211c, 212c, 213c, 214c, 215c, 216c, 217c, and 218c (all analogous to first conductive terminal 110c in FIG. 1C) are formed in multiple layers via multiple deposition and etching process steps. Each of these layers are electrically isolated from each other by intervening insulating layers 251c, 252c, 253c, 254c, 255c, 256c, 257c, and 258c. Finally, a vertical conductive structure 220c provides a second sidewall contact (analogous to second conductive terminal 120c in FIG. 1C) for all eight nanotube fabric elements 231c-238c. Responsive to electrical stimuli applied between its associated first sidewall conductive terminal 211c-218c and the common second sidewall contact 220c, each nanotube fabric element can be uniquely addressed and adjusted into a desired nonvolatile resistive state.

Within array cells 201 and 202 depicted in FIGS. 2A and 2B and the multielement array 203 depicted in FIG. 2C, each of the two-terminal resistive change elements is capable of being adjusted between different resistive states by applying electrical stimuli, typically one or more programming pulses of specific voltages and pulse widths, across the nanotube fabric element (230a in FIG. 2A, 230b in FIG. 2B, and 231c-238c in FIG. 2C). By controlling the magnitude and the duration of this electrical current, the nanotube fabric element (230a in FIG. 2A, 230b in FIG. 2B, and 231c-238c in FIG. 2C) can be adjusted among a plurality of resistive states.

The state of the array cells depicted in FIGS. 2A, 2B, and 2C can be determined by applying a DC test voltage, for example, but not limited to, 0.5V, between the first conductive terminal (210a in FIG. 2A, 210b in FIG. 2B, and 211c-218c in FIG. 2C) and the second conductive terminal (220a in FIG. 2A, 220b in FIG. 2B, and 220c in FIG. 2C) and measuring the current through the nanotube fabric element (230a in FIG. 2A, 230b in FIG. 2B, and 231c-238c in FIG. 2C). In some applications this current can be measured by using a power supply with a current feedback output, for example, a programmable power supply or a sense amplifier. Alternatively, the state of the array cells depicted in FIGS. 2A, 2B, and 2C can also be determined by driving a fixed DC current, for example, but not limited to, 1 μA, through the nanotube fabric element (230a in FIG. 2A, 230b in FIG. 2B, and 231c-238c in FIG. 2C) and measuring the voltage across the first conductive terminal (210a in FIG. 2A, 210b in FIG. 2B, and 211c-218c in FIG. 2C) and the second conductive terminal (220a in FIG. 2A, 220b in FIG. 2B, and 220c in FIG. 2C). Methods for programming and reading the state of two-terminal nanotube switching devices as described above is discussed in more detail within the incorporated references (for example, U.S. Pat. No. 7,781,862 to Bertin et al., as discussed in more detail above).

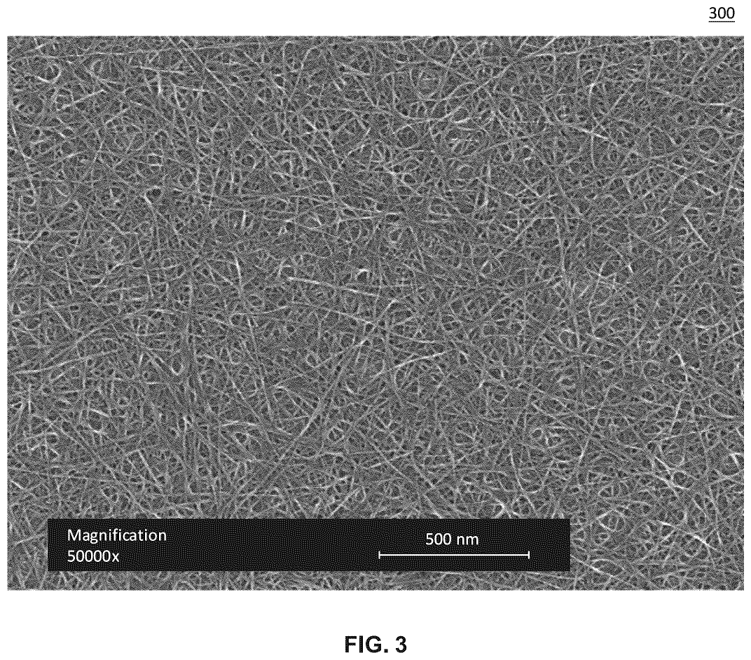

FIG. 3 is an SEM image of an exemplary nanotube fabric 300 shown at 50,000× magnification. As shown in FIG. 3, nanotube fabric 300 is comprised of a plurality of individual nanotube elements forming an unordered network of conductive paths across and through the fabric. The nanotube fabric 300 was formed via multiple spin coating operations wherein a solution of functionalized and purified nanotubes suspended in a liquid medium was spin coated onto a silicon wafer. The spin coating operation was performed three times, and the resulting deposition then put through a high temperature anneal process to realize a fully formed nanotube fabric 300 as shown in FIG. 3. As discussed above, methods for forming nanotube fabrics are taught in greater detail in the incorporated references (for example, U.S. Pat. No. 7,375,369 to Sen et al.).

It should be noted that a number of the illustrations within the figures of the present disclosure (most notably, FIGS. 1A-1C, 5, 9, 10, 11, and 12) depict nanotube fabrics using simplified illustrations for ease of explanation purposes with respect to the methods of the present disclosure. In particular, the relative sizes, positions, and density of the nanotube elements depicted within these figures have been designed such as to logically illustrate the relative orientation positions and orientations of nanotubes within a nanotube fabric layer and have not been drawn to any scale. Indeed, as will be clear to those skilled in the art, within the SEM image of actual nanotube fabric layer 300 shown in FIG. 3, nanotube elements are packed much closer together with substantial overlapping and contact between adjacent nanotube elements as compared to the simplified illustrations show in FIGS. 1A-1C, for example. To this end, FIG. 3 has been included to provide a realistic image of a nanotube fabric to complement the essentially schematic representations depicted in FIGS. 1A-1C, 5, 9, 10, 11, 12, 13, and 14.

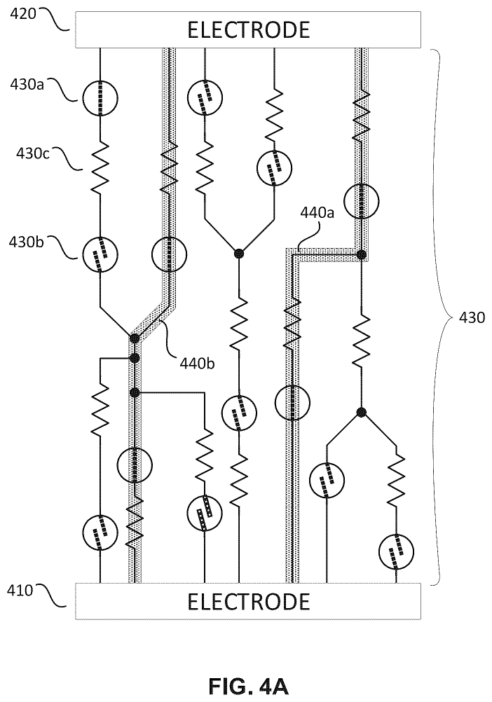

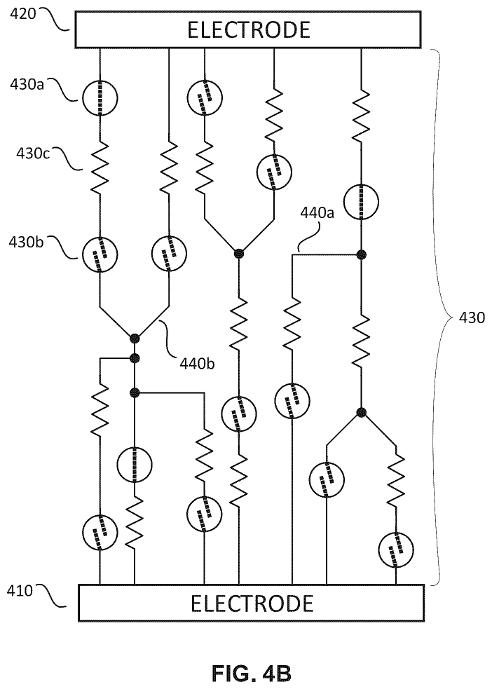

FIGS. 4A and 4B are schematic diagrams modeling the switching function of nanotube fabrics with a resistive-switch network 430. Within both FIGS. 4A and 4B, a nanotube fabric is modeled as a network of resistive elements 430c, closed switch elements 430a, and open switch elements 430b providing an adjustable conductive path between a first electrode 410 (analogous to bottom conductive terminal 110a in FIG. 1A, first bottom conductive terminal 110b in FIG. 1B, and first sidewall conductive terminal 110c in FIG. 1C) and second electrode 420 (analogous to top conductive terminal 120a in FIG. 1A, second bottom conductive terminal 120b in FIG. 1B, and second sidewall conductive terminal 120c in FIG. 1C). A plurality of closed switch elements 430a and open switch elements 430b are representative of activated and deactivated switching sites, respectively, within a nanotube fabric. Within the schematic diagram model of FIGS. 4A and 4B these open and closed switching elements control the presence or absence of conductive paths between first electrode 410 and second electrode 420 and are used to model the behavior of switching sites within a nanotube fabric, which can be adjusted between a relatively low conductive state (represented by open switch elements 430b) and a relatively high conductive state (represented by closed switching elements 430a).

Looking to FIG. 4A, resistive-switch network 430 is configured to provide two conductive pathways, 440a and 440b between first electrode 410 and second electrode 420. Each of the two conductive paths 440a and 440b (highlighted in FIG. 4A for ease of illustration) includes two closed switch elements 430a, analogous to two activated switching sites within a nanotube fabric. As such, the state of resistive-switch network 430 as depicted in FIG. 4A represents a nanotube fabric within a two-terminal nanotube switching device which has been rendered into a relatively low resistance SET state. Looking next to FIG. 4B, the electrical state of resistive-switch network has been changed such that one of the switch elements within each of paths 440a and 440b has been rendered into an open state (represented in FIG. 4B now with open switch elements 430b). With the resistive-switch network 430 in this state, no conductive paths exist through the network 430 and, consequently, there is no conductive path between first electrode 410 and second electrode 420. As such, the state of resistive-switch network 430 as depicted in FIG. 4B represents a nanotube fabric within a two-terminal nanotube switching device which has been rendered into a relatively high resistance RESET state.

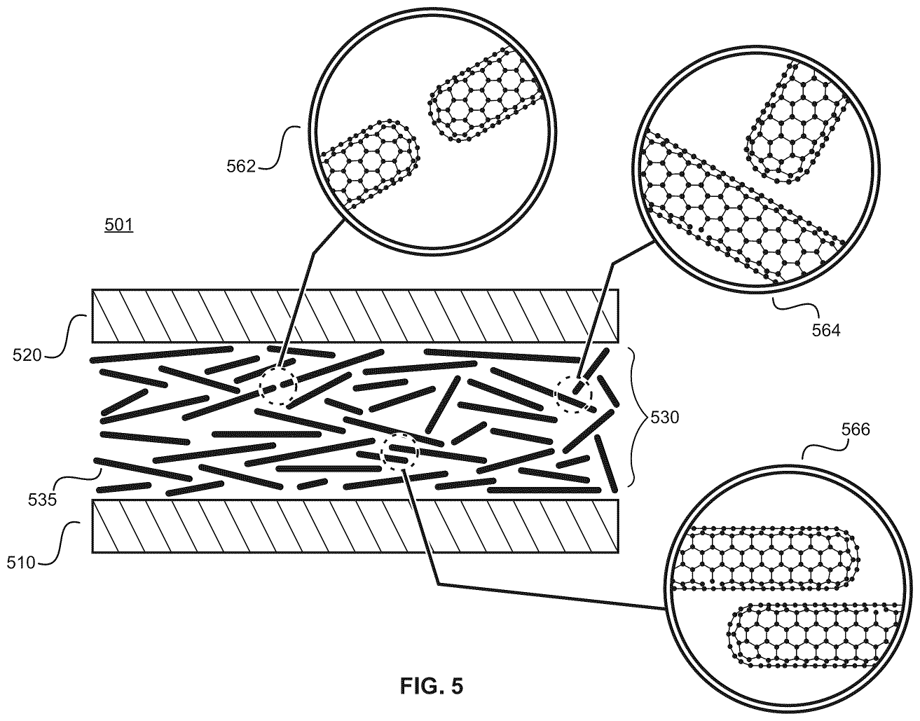

FIG. 5 is a diagram of a two-terminal nanotube switching device 501 highlighting three different switching sites 562, 564, and 566 within a nanotube fabric 530. Two-terminal switching device 501 is a vertically oriented nanotube switching device similar to device 101 depicted in FIG. 1A. As with device 101 of FIG. 1A, the nanotube switching device 501 of FIG. 5 comprises bottom conductive terminal 510, top conductive terminal 520, and nanotube fabric 530 providing an adjustable conductive path between the two terminals 510 and 520. As discussed in detail above, nanotube fabric 530 is comprised of a plurality of individual nanotube elements 535. Without wishing to be bound by theory, it is surmised that the physical interface regions between the individual nanotube elements 535 create switching sites throughout the nanotube fabrics at points where different nanotube elements 535 come very close together. Responsive to electrical stimuli applied across the fabric (as described in detail above) nanotube elements will come together and move apart at these physical interface regions, creating low and high resistive pathways, respectively, from one nanotube to the next. In this way, a plurality of adjustable electrical pathways are present throughout the nanotube fabric and can be modulated to adjust the overall resistance of the nanotube fabric.

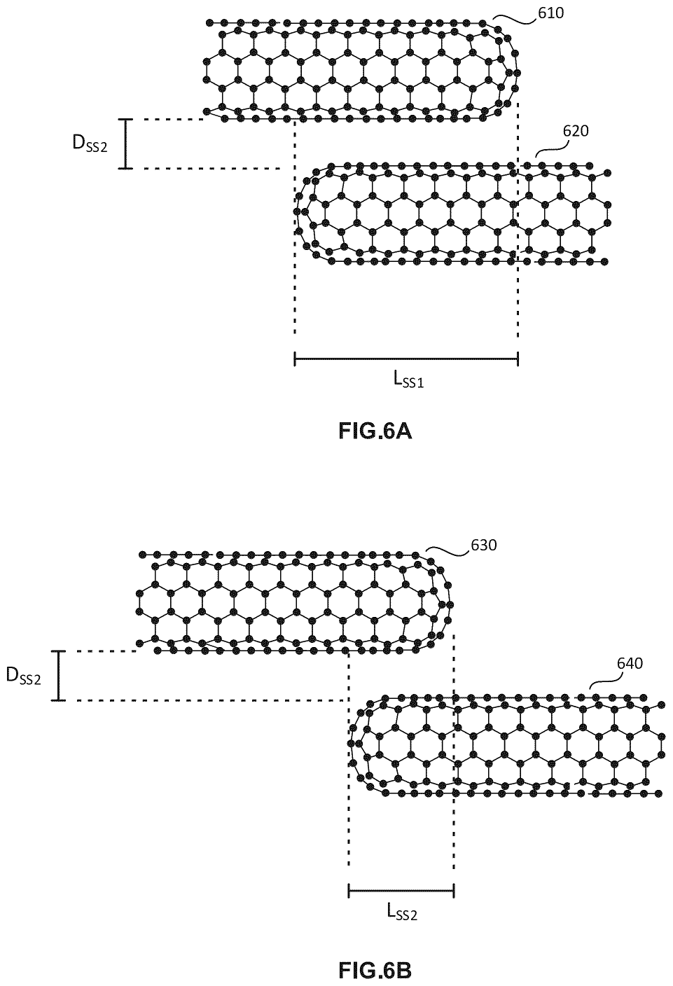

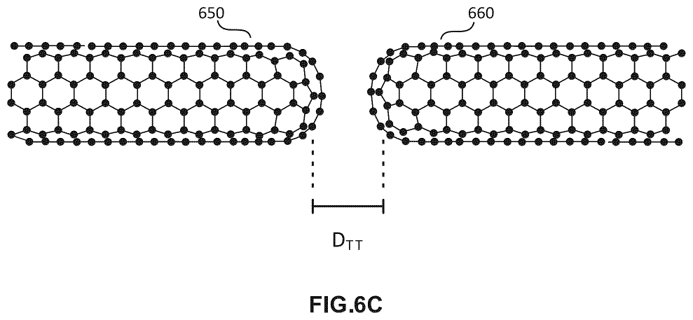

FIG. 5 illustrates three different ways two nanotube elements 535 within a nanotube fabric 530 can physically interface with each other to realize a switching site. Switching site 562 illustrates an end-to-end physical interface wherein the endpoint of one nanotube is in close proximity to the endpoint of another nanotube. Such an end-to-end physical interface is shown in greater detail in FIG. 6C. Switching site 566 illustrates a sidewall-to-sidewall interface wherein the sidewall of one nanotube is in close proximity to the sidewall of another nanotube. Such a sidewall-to-sidewall physical interface is shown in greater detail in FIGS. 6A and 6B. Finally, switching site 564 illustrates an end-to-sidewall physical interface wherein the endpoint of one nanotube is in close proximity with the sidewall of another nanotube.

Again, without wishing to be bound by theory, within nanotube fabrics the effective electrical resistance between adjacent nanotube elements is a function of the geometry of the overlapping regions of the two nanotube elements (i.e., how much of each nanotube is within the close proximity region) and the atom-to-atom distance between the two nanotube elements (i.e., the effective gap between the closest point of each nanotube). To illustrate this point, FIG. 6A shows a first a sidewall-to-sidewall physical interface (analogous to switching junction 566 in FIG. 5) between a first nanotube element 610 and a second nanotube element 620. The sidewalls of the two nanotubes 610 and 620 are separated by a distance D_{SS1} over an overlap length of L_{SS1}. As discussed above, the physical interface region between first nanotube 610 and second nanotube 620 creates a switching site. The effective electrical resistance of this switching site is a function of D_{SS1} and L_{SS1}, which can be adjusted via an electrical stimulus applied across the fabric, which will induce the nanotubes to either move closer together, decreasing D_{SS1} and the resistance of the switching site, or to move farther apart, increasing D_{SS1} and the resistance of the switching site. Within such a switching operation however, the overlap length L_{SS1}, which also contributes to the resistivity of the switching site, remains essentially the same.

FIG. 6B shows a second sidewall-to-sidewall interface between a third nanotube element 630 and a fourth nanotube element 640. As with the first sidewall-to-sidewall interface shown in FIG. 6A, the sidewalls of this second pair of nanotubes (630 and 640) are separated by a distance D_{SS2} over an overlap length of L_{SS2}. This physical interface region between the two nanotubes (630 and 640) creates a switching site, the electrical resistance of which can be adjusted by inducing nanotubes 630 and 640 to move closer together (decreasing D_{SS2}) or further apart (increasing D_{SS2}). In this way, as with the switching site depicted by the sidewall-to-sidewall interface within FIG. 6A, the resistivity of the switching site depicted in FIG. 6B can be adjusted responsive to an applied electrical stimulus. However, as with the switching site of FIG. 6A, the overlap length of nanotubes 630 and 640, L_{SS2}, contributes to the overall resistivity of the switching site.

As can be observed by comparing FIGS. 6A and 6B, L_{SS2} is significantly shorter than L_{SS1}. This difference illustrates the fact that within a nanotube fabric (for example, when used in any of the device configurations detailed in FIGS. 1A-1C, as discussed above) the overlap length between pairs of adjacent nanotubes will vary significantly across the fabric (i.e., some nanotube pairs will overlap more than others). This difference in interface overlap length can, in certain applications, significantly vary the effective electrical resistance between pairs of nanotubes, even with each pair spaced the same distance apart. Within such applications, the electrical resistance observed at switching sites realized at the physical interfaces between different pairs of nanotubes can vary significantly for both low resistance states and high resistance states. Such variation can, in these applications, lead to a wide distribution of SET state and RESET state resistance values as compared from one device to another. Further, the electrical energy required to induce nanotubes to move away from each other for sidewall-to-sidewall physical interfaces is a function of this overlap length (L_{SS1} and L_{SS2}). As such, the switching energy (e.g., the magnitude of an applied switching voltage or current) required to adjust these switching sites can also vary significantly. In certain applications, this variation in switching site response to an applied switching stimulus can introduce nonuniformity device to device.

Looking now to FIG. 6C, an end-to-end interface between a fifth nanotube 650 and a sixth nanotube 660 (analogous to switching site 566 in FIG. 5) is shown. Within this end-to-end interface, the endpoints of each nanotube 650 and 660 are separated by a distance D_{TT}. As with the sidewall-to-sidewall interfaces shown in FIGS. 6A and 6C, the effective electrical resistance between nanotube 650 and nanotube 660 is a function of this separation distance D_{TT}. As discussed above, the physical interface region between first nanotube 610 and second nanotube 620 creates a switching site. The effective electrical resistance of this switching site is a function of D_{TT}, which can be adjusted via an electrical stimulus applied across the fabric, which will induce the nanotubes to either move closer together, decreasing D_{TT} and the resistance of the switching site, or to move farther apart, increasing D_{TT} and the resistance of the switching site. Unlike the sidewall-to-sidewall switching sites shown in FIGS. 6A and 6B, however, there is no overlap region between nanotubes 650 and 660. As such, the nonuniformity issues introduced by sidewall-to-sidewall switching sites within certain application with respect to distribution of switching site resistance values and switching energy requirements (as discussed above, with respect to FIGS. 6A and 6B) are not present in end-to-end switching sites, like the one depicted in FIG. 6C.

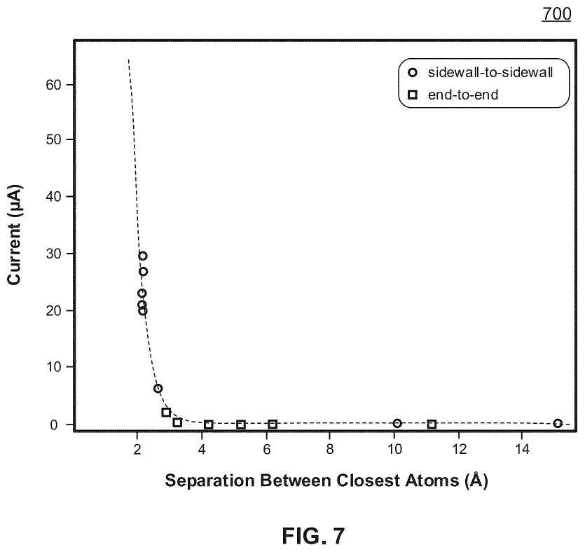

FIG. 7 is a plot of an atomistic density-functional theory (DST) simulation, graphing the current through different modeled nanotube interfaces as a function of the distance between those nanotubes. Within the plot 700 of FIG. 7, the data points represented by open circles are sidewall-to-sidewall nanotube interfaces (switching sites), and the points represented by open squares are end-to-end nanotube interfaces (switching sites). The plot 700 shows that the interface current has an exponential dependance on separation distance, and that only small physical displacements are required to significantly alter the current. As can be observed within plot 700, the sidewall-to-sidewall nanotube interfaces show significantly more variation in conductivity (i.e., show significant differences in current across the nanotube-to-nanotube junction) as compared to the end-to-end nanotube interfaces. This is especially true, for nanotube pairs with very little atomic separation distance. As discussed above, in certain applications, it is the uncontrolled degree of sidewall overlap within sidewall-to-sidewall nanotube interfaces that creates this wide distribution.

The modelling data of FIG. 7 illustrates that when forming a nanotube fabric to use within a two-terminal nanotube switching device, it can be, in certain applications where uniformity of resistance distribution and response to switching stimuli are important, highly desirable to use fabrics dominated by end-to-end switching sites across the nanotube fabric. However, as nanotube fabrics are typically formed from solution deposited nanotubes (as described in detail above and within the incorporated references), it would be difficult to control the type of nanotube physical interfaces within a nanotube fabric formation operation. To this end, the present disclosure provides methods of introducing break-type switching sites within a fully formed nanotube fabric that exhibit the uniformity benefits of end-to-end switching sites, as described above.

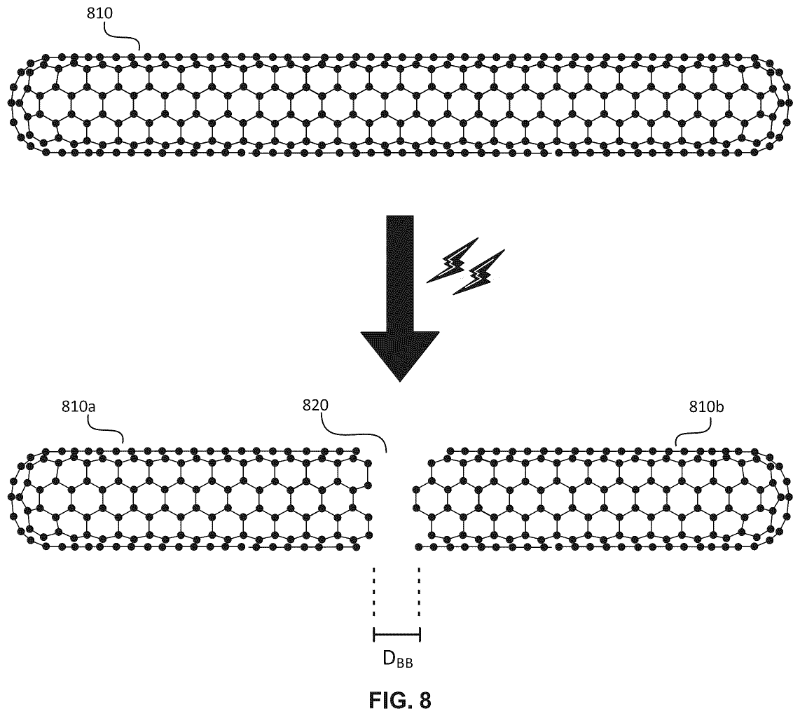

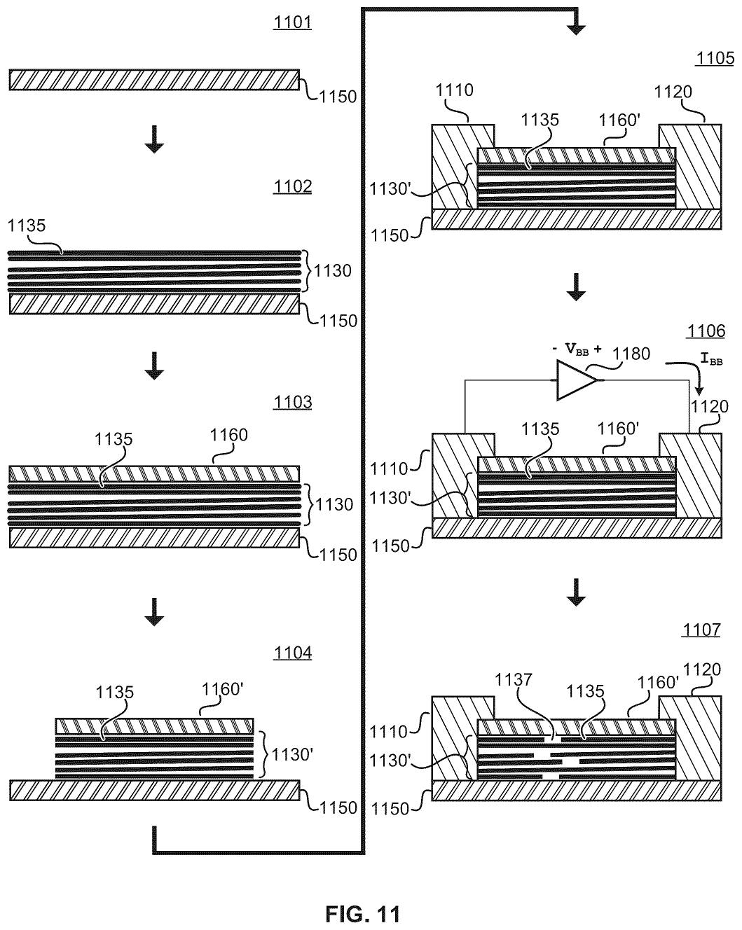

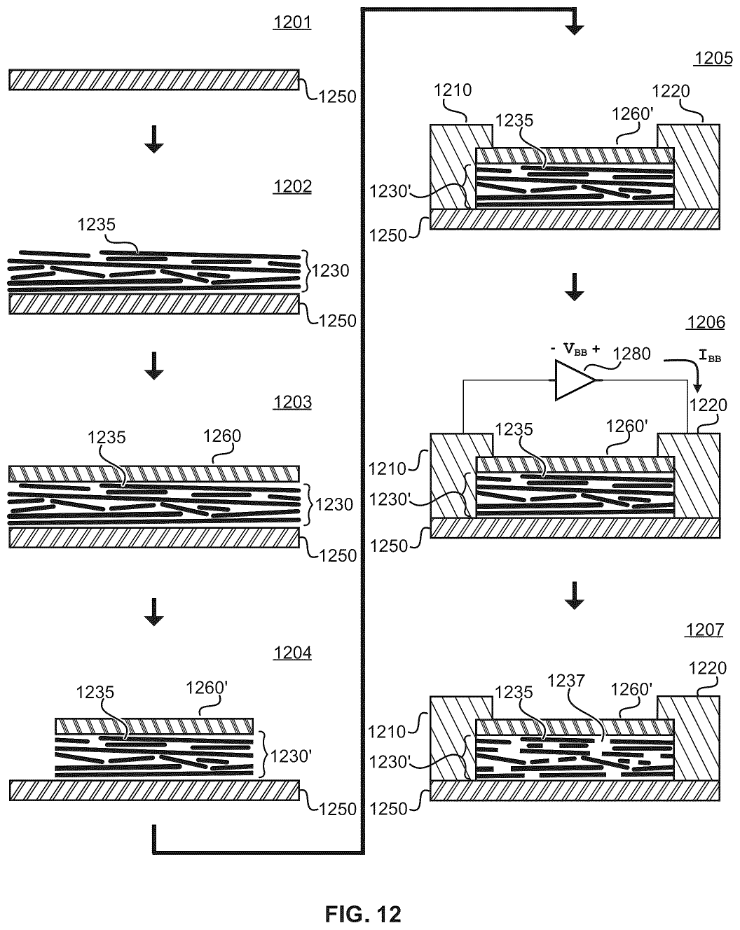

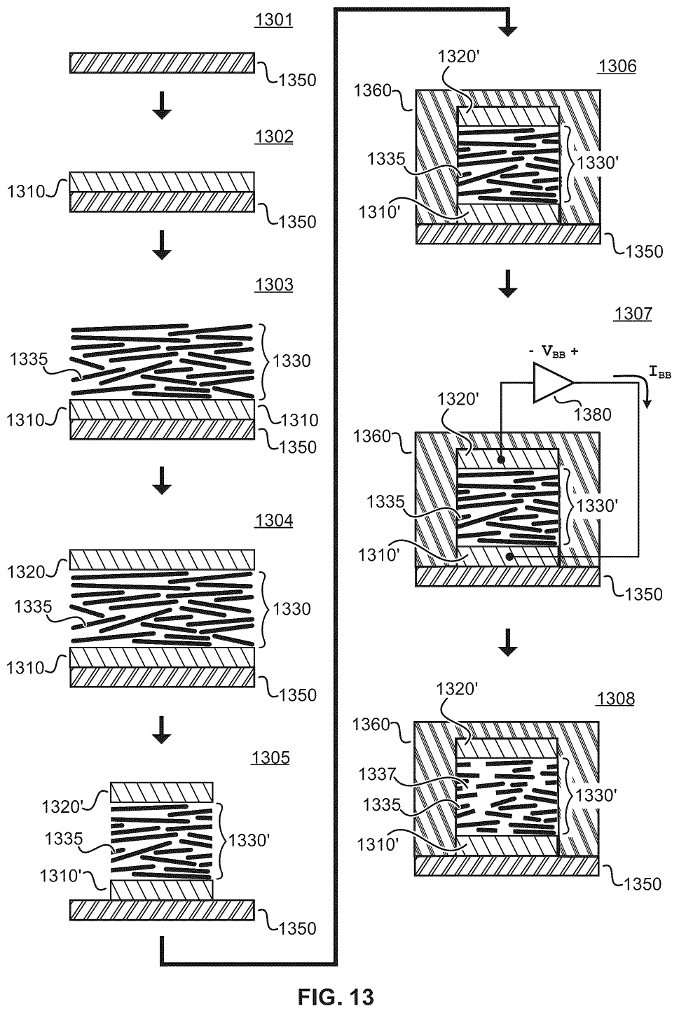

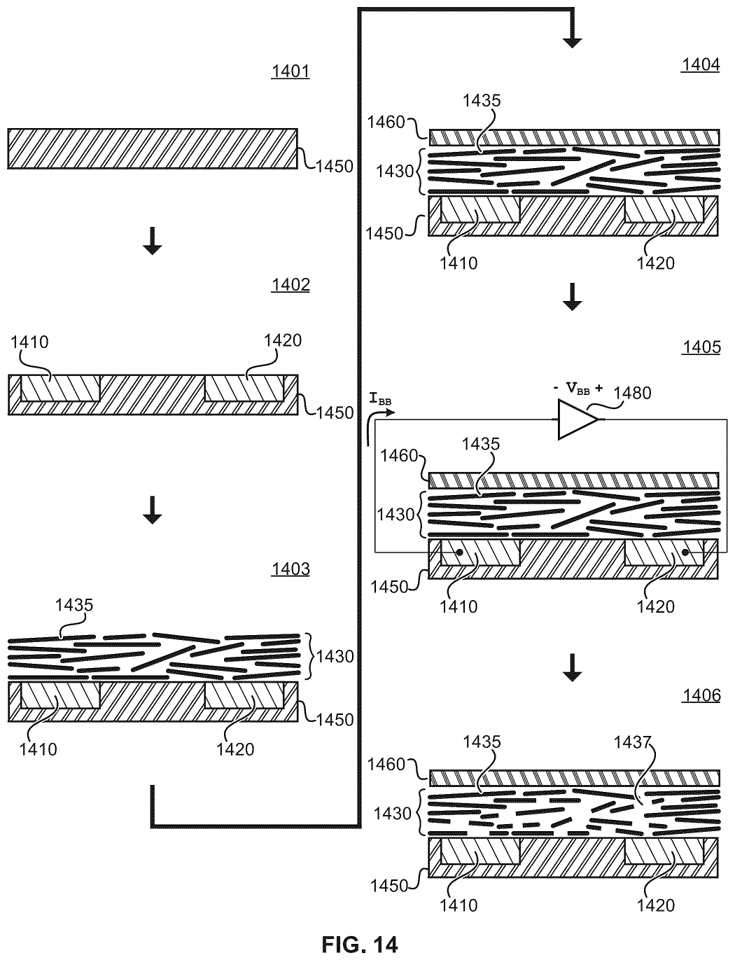

FIG. 8 illustrates an operation which introduces a break within a nanotube element 810. Such an operation is representative of process steps 906 in FIG. 9, 1006 in FIG. 10, 1106 in FIG. 11, 1206 in FIG. 12, 1307 in FIGS. 13, and 1405 in FIG. 14 wherein breaks are created in a plurality of nanotubes across an entire nanotube fabric. But as an initial point of explanation, FIG. 8 illustrates the creation of a single break 820 in a single nanotube element 810. As will be discussed below with respect to FIGS. 9-14, by applying a high energy electrical stimulus through a nanotube element 810, a break 820 within that nanotube element can be introduced. This break 820 creates a separation distance D_{BB} between the first end 810aof nanotube 810 and the second end 810b of nanotube 810 that is analogous to the separation distance D_{TT} between nanotube 650 and nanotube 660 within the end-to-end nanotube physical interface shown in FIG. 6C. As such, break 820 becomes a switching site (termed a “break-type” switching site within the present disclosure) within nanotube 810, modulating a conductive path between the first end 810a and the second end 810b of nanotube element 810. As with the end-to-end switching site described above with respect to FIG. 6C, first end 810a and second end 810b of nanotube 810 can be induced to move closer together (reducing D_{BB} and lowering the effective electrical resistance across break 820) and subsequently induced to move further apart again (at least partially restoring D_{BB}, and increasing the effective electrical resistance across break 820). In this way, break-type switching site 820 functions like the end-to-end switching site of FIG. 6C. As will be discussed within FIGS. 9-14, the present disclosure provides methods of forming nanotube switching devices with a plurality of break-type switching sites throughout the fabric. Such devices, in certain applications, will exhibit significantly more uniform response to programming voltages, tighter distributions of SET and RESET resistance values, and require lower switching energy as compared with devices comprising nanotube fabrics including only mixtures of sidewall-to-sidewall switching sites, end-to-sidewall switching sites, and end-to-end switching sites.

FIG. 9 is a process flow diagram illustrating a first method of forming a two-terminal nanotube switching device with a plurality of break-type switching sites according to the methods of the present disclosure. This first method uses relatively long nanotube elements 935 and results in breaks 937 distributed across an etched nanotube fabric 930′. In a first process step 901, a dielectric substrate layer 950 is provided. This dielectric substrate layer 950 can be formed from a variety of dielectric materials including, but not limited to, silicon, silicon rich oxide (SRO), or aluminum oxide. In a next process step 902, a nanotube fabric 930 is formed over dielectric substrate layer 950. Nanotube fabric 930 is comprised of a plurality of nanotube elements 935, which are relatively long compared to the width of the device, as will be discussed in more detail with respect to process steps 904 and 905 below. Nanotube fabric 930 is preferably formed from a spin-coating operation of purified, functionalized nanotubes suspended in an application solution, as discussed in detail above and in the incorporated references. However, within certain applications, nanotube fabric 930 could also be formed via a dip-coating operation or a spray-coating operation.

In a next process step 903 a protective coating layer 960 is formed over nanotube fabric layer 930. Protective coating layer 960 is formed from suitable dielectric protective material such as, but not limited to, silicon nitride. In a next process step 904, nanotube fabric layer 930 and protective coating layer 960 are etched to form etched nanotube fabric layer 930′ covered by etched protective layer 960′. These two etched material layers 930′ and 960′ are etched back to realize a nanotube fabric that conforms to the desired geometric dimensions of the two-terminal nanotube switching device, with nanotube fabric sidewalls formed on each side of etched nanotube fabric 930′. The etching process may be performed using an isotropic etch, for example an oxygen plasma etch. Methods for etching nanotube fabrics are discussed further in the incorporated references (for example, within U.S. Patent Publication 2021/0399219).

Within the method of FIG. 9, etched nanotube fabric 930′ is comprised of nanotube elements 935 that are relatively long compared to the width of the etched nanotube fabric 930′. That is, after the etching operation of process step 904, many of the nanotubes 935 within etched nanotube fabric 930′ have lengths equal to (and span the entirety of) the width of the etched nanotube fabric 930′. This results because, within the method of FIG. 9, nanotube fabric 930 is originally formed with nanotube elements 935 having lengths, on average, that are longer than the desired device width prior to the etching operation. Consequently, etched nanotube fabric 930′ is comprised of a plurality of nanotube elements 935 which span the entire width of etched nanotube fabric 930′, from sidewall to sidewall.

In a next process step 905, a first consecutive element 910 and a second conductive element 920 are formed at opposite ends of etched nanotube fabric 930′ such that etched nanotube fabric layer 930′ provides an adjustable conductive path between first conductive element 910 and second conductive element 920. First conductive element 910 and second conductive element 920 are formed from a conductive material such as, but not limited to, Al, TiN, TaN, W, Ru, RuN, or RuO. Referring back to the exemplary device structure of FIG. 1C (discussed in detail above), etched nanotube fabric 930′ is analogous to nanotube fabric 130c in FIG. 1C, first conductive element 910 is analogous to first conductive terminal 110c in FIG. 1C, and second conductive element 920 is analogous to second conductive terminal 120c in FIG. 1C. In this way, basic structure of a two-terminal switching device has been formed. As discussed above, within the method of FIG. 9, as relatively long (as compared to the nanotube fabric width) nanotube elements 935 were used to form nanotube fabric 930, etched nanotube fabric 935 is comprised of a plurality of nanotube elements 935 which each contact first conductive element 910 at one endpoint and contact second conductive element 920 at the other endpoint. Within some applications, the lengths of nanotubes 935 are selected such that substantially all of the nanotubes 935 within the etched nanotube fabric 930′ span the distance between first conductive element 910 and second conductive element 920. Within other applications, the lengths of nanotubes 935 are selected such that only a percentage (for example, but not limited to, on the order of 75%, 50%, or 25%) of the nanotubes 935 within the etched nanotube fabric 930′ span the distance between first conductive element 910 and second conductive element 920.

In next process step 906, a driver 980 is used to apply an electrical stimulus across first conductive element 910 and second conductive element 920. This applied electrical stimulus drives a voltage, V_{BB}, across, and a current, I_{BB}, through etched nanotube fabric 930′ as each end of etched nanotube fabric 930′ is in electrical contact with one of conductive elements 910 and 920, each against a different sidewall of etched nanotube fabric 930′. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 935 within etched nanotube fabric 930′. Depending on the needs of the specific application, the application of this electrical stimulus can be performed through backend metallization wherein first conductive element 910 and second conductive element 920 are pinned out to pads. In next process step 907, breaks 937 in nanotube elements 935 resulting from this applied electrical stimulus are visible. It should be noted that responsive to the applied electrical stimulus, an individual nanotube element 935 may exhibit multiple breaks or a single break. Additionally, an individual nanotube element 935 may exhibit no breaks at all. That is, the methods of the present disclosure do not require that every nanotube element 935 exhibit the same number of breaks or even breaks of equal size. Instead, the methods of the present disclosure provide that the applied electrical stimulus introduces a plurality of breaks 937 distributed across the etched nanotube fabric 930′ as a whole.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within etched nanotube fabric 930′. As discussed previously, these break-type switching sites will provide uniformity in switching resistance from device to device as well as lower switching energy being required to adjust etched nanotube fabric 930′ from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites with the nanotube fabric of a two-terminal nanotube switching device create uniform device-to-device performance, which is highly desirable in certain applications.

FIG. 10 is a process flow diagram illustrating a second method of forming a two-terminal nanotube switching device with a plurality of break-type switching sites according to the methods of the present disclosure. This second method uses relatively short nanotube elements 1035 and results in breaks 1037 distributed across an etched nanotube fabric 1030′. In a first process step 1001, a dielectric substrate layer 1050 is provided. This dielectric substrate layer 1050 can be formed from a variety of dielectric materials including, but not limited to, silicon, silicon rich oxide (SRO), or aluminum oxide. In a next process step 1002, a nanotube fabric 1030 is formed over dielectric substrate layer 1050. Nanotube fabric 1030 is comprised of a plurality of nanotube elements 1035, which are generally shorter than the width of the device, as will be discussed in more detail with respect to process steps 1004 and 1005 below. Nanotube fabric 1030 is preferably formed from a spin-coating operation of purified, functionalized nanotubes suspended in an application solution, as discussed in detail above and in the incorporated references. However, within certain applications, nanotube fabric 1030 could also be formed via a dip-coating operation or a spray-coating operation.

In a next process step 1003 a protective coating layer 1060 is formed over nanotube fabric layer 1030. Protective coating layer 1060 is formed from suitable dielectric protective material such as, but not limited to, silicon nitride. In a next process step 1004, nanotube fabric layer 1030 and protective coating layer 1060 are etched to form etched nanotube fabric layer 1030′ covered by etched protective layer 1060′. These two etched material layers 1030′ and 1060′ are etched back to realize a nanotube fabric that conforms to the desired geometric dimensions of the two-terminal nanotube switching device, with nanotube fabric sidewalls formed on each side of etched nanotube fabric 1030′. The etching process may be performed using an isotropic etch, for example an oxygen plasma etch. Methods for etching nanotube fabrics are discussed further in the incorporated references (for example, within U.S. Patent Publication 2021/0399219).

Within the method of FIG. 10, etched nanotube fabric 1030′ is comprised mostly of nanotube elements 1035 that are, in general, shorter than the width of the etched nanotube fabric 1030′. That is, after the etching operation of process step 1004, many of the nanotubes 1035 within etched nanotube fabric 1030′ have lengths such that they do not span the entire width of etched nanotube fabric 1030′. Consequently, etched nanotube fabric 1030′ is comprised of a plurality of nanotube elements 1035 which do not span the entire width of etched nanotube fabric 1030′, from sidewall to sidewall. This results in a plurality of end-to-end, sidewall-to-sidewall, and end-to-sidewall switching sites (as discussed in detail above with respect to FIGS. 5 and 6A-6C) being present in nanotube fabric 1030 as deposited.

In a next process step 1005, a first conductive element 1010 and a second conductive element 1020 are formed at opposite ends of etched nanotube fabric 1030′ such that etched nanotube fabric layer 1030′ provides an adjustable conductive path between first conductive element 1010 and second conductive element 1020. First conductive element 1010 and second conductive element 1020 are formed from a conductive material such as, but not limited to, Al, TiN, TaN, W, Ru, RuN, or RuO. Referring back to the exemplary device structure of FIG. 1C (discussed in detail above), etched nanotube fabric 1030′ is analogous to nanotube fabric 130c in FIG. 1C, first conductive element 1010 is analogous to first conductive terminal 110c in FIG. 1C, and second conductive element 1020 is analogous to second conductive terminal 120c in FIG. 1C. In this way, the basic structure of a two-terminal switching device has been formed. As discussed above, within the method of FIG. 10, as relatively short (as compared to the nanotube fabric width) nanotube elements 1035 were used to form nanotube fabric 1030, etched nanotube fabric 1030′ is comprised of a plurality of types of switching sites distributed throughout the nanotube fabric. As discussed in detail above, in certain applications the variation in the behavior of these different types of switching sites (in terms of interface resistance and switching energy required to switch) can result in non-uniformity across multiple devices. As such, next process step 1006 is used to introduce a plurality of break-type switching sites within etched nanotube fabric 1030′ to increase the uniformity of performance in two-terminal nanotube switching devices formed according to this method of the present disclosure.

In next process step 1006, a driver 1080 is used to apply an electrical stimulus across first conductive element 1010 and second conductive element 1020. This applied electrical stimulus drives a voltage, V_{BB}, across, and a current, I_{BB}, through etched nanotube fabric 1030′ as each end of etched nanotube fabric 1030′ is in electrical contact with one of conductive elements 1010 and 1020, each against a different sidewall of etched nanotube fabric 1030′. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1035 within etched nanotube fabric 1030′. Depending on the needs of the specific application, the application of this electrical stimulus can be performed through backend metallization wherein first conductive element 1010 and second conductive element 1020 are pinned out to pads. In next process step 1007, breaks 1037 in nanotube elements 1035 resulting from this applied electrical stimulus are visible. It should be noted that responsive to the applied electrical stimulus, an individual nanotube element 1035 may exhibit multiple breaks or a single break. Additionally, an individual nanotube element 1035 may exhibit no breaks at all. That is, the methods of the present disclosure do not require that every nanotube element 1035 exhibit the same number of breaks or even breaks of equal size. Instead, the methods of the present disclosure provide that the applied electrical stimulus introduces a plurality of breaks 1037 distributed across the etched nanotube fabric 1030′ as a whole.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within etched nanotube fabric 1030′ over the other types of switching sites originally present in etched nanotube fabric 1030′ when initially formed. As discussed previously, these break-type switching sites will provide uniformity in switching resistance from device to device as well as lower switching energy being required to adjust etched nanotube fabric 1030′ from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites within the nanotube fabric of a two-terminal nanotube switching device create uniform device-to-device performance, which is highly desirable in certain applications.

FIG. 11 is a process flow diagram illustrating a third method of forming a two-terminal nanotube switching device with a plurality of break-type switching sites according to the methods of the present disclosure. As with the method detailed by FIG. 9, this third method uses relatively long nanotube elements 1135 but results in breaks 1137 located largely within a single region within etched nanotube fabric 1130′. In a first process step 1101, a dielectric substrate layer 1150 is provided. This dielectric substrate layer 1150 can be formed from a variety of dielectric materials including, but not limited to, silicon, silicon rich oxide (SRO), or aluminum oxide. In a next process step 1102, a nanotube fabric 1130 is formed over dielectric substrate layer 1150. Nanotube fabric 1130 is comprised of a plurality of nanotube elements 1135, which are relatively long compared to the width of the device, as will be discussed in more detail with respect to process steps 1104 and 1105 below. Nanotube fabric 1130 is preferably formed from a spin-coating operation of purified, functionalized nanotubes suspended in an application solution, as discussed in detail above and in the incorporated references. However, within certain applications, nanotube fabric 1130 could also be formed via a dip-coating operation or a spray-coating operation.

In a next process step 1103 a protective coating layer 1160 is formed over nanotube fabric layer 1130. Protective coating layer 1160 is formed from suitable dielectric protective material such as, but not limited to, silicon nitride. In a next process step 1104, nanotube fabric layer 1130 and protective coating layer 1160 are etched to form etched nanotube fabric layer 1130′ covered by etched protective layer 1160′. These two etched material layers 1130′ and 1160′ are etched back to realize a nanotube fabric that conforms to the desired geometric dimensions of the two-terminal nanotube switching device, with nanotube fabric sidewalls formed on each side of etched nanotube fabric 1130′. The etching process may be performed using an isotropic etch, for example an oxygen plasma etch. Methods for etching nanotube fabrics are discussed further in the incorporated references (for example, within U.S. Patent Publication 2021/0399219).

As with the method of FIG. 9, within the method of FIG. 11, etched nanotube fabric 1130′ is comprised of nanotube elements 1135 that are relatively long compared to the width of the etched nanotube fabric 1130′. That is, after the etching operation of process step 1104, many of the nanotubes 1135 within etched nanotube fabric 1130′ have lengths equal to (and span the entirety of) the width of the etched nanotube fabric 1130′. This results because, within the method of FIG. 11, nanotube fabric 1130 is originally formed with nanotube elements 1135 having lengths, on average, that are longer than the desired device width prior to the etching operation. Consequently, etched nanotube fabric 1130′ is comprised of a plurality of nanotube elements 1135 which span the entire width of etched nanotube fabric 1130′, from sidewall to sidewall.

In a next process step 1105, a first conductive element 1110 and a second conductive element 1120 are formed at opposite ends of etched nanotube fabric 1130′ such that etched nanotube fabric layer 1130′ provides an adjustable conductive path between first conductive element 1110 and second conductive element 1120. First conductive element 1110 and second conductive element 1120 are formed from a conductive material such as, but not limited to, Al, TiN, TaN, W, Ru, RuN, or RuO. Referring back to the exemplary device structure of FIG. 1C (discussed in detail above), etched nanotube fabric 1130′ is analogous to nanotube fabric 130c in FIG. 1C, first conductive element 1110 is analogous to first conductive terminal 110c in FIG. 1C, and second conductive element 1120 is analogous to second conductive terminal 120c in FIG. 1C. In this way, the basic structure of a two-terminal switching device has been formed.

As discussed above, within the method of FIG. 11, as relatively long (as compared to the nanotube fabric width) nanotube elements 1135 were used to form nanotube fabric 1130, etched nanotube fabric 1135 is comprised of a plurality of nanotube elements 1135 which each contact first conductive element 1110 at one endpoint and contact second conductive element 1120 at the other endpoint. Within some applications, the lengths of nanotubes 1135 are selected such that substantially all of the nanotubes 1135 within the etched nanotube fabric 1130′ span the distance between first conductive element 1110 and second conductive element 1120. Within other applications, the lengths of nanotubes 1135 are selected such that only a percentage (for example, but not limited to, on the order of 75%, 50%, or 25%) of the nanotubes 1135 within the etched nanotube fabric 1130′ span the distance between first conductive element 1110 and second conductive element 1120.

In next process step 1106, a driver 1180 is used to apply an electrical stimulus across first conductive element 1110 and second conductive element 1120. This applied electrical stimulus drives a voltage, V_{BB}, across, and a current, I_{BB}, through etched nanotube fabric 1130′ as each end of etched nanotube fabric 1130′ is in electrical contact with one of conductive elements 1110 and 1120, each against a different sidewall of etched nanotube fabric 1130′. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1135 within etched nanotube fabric 1130′. Depending on the needs of the specific application, the application of this electrical stimulus can be performed through backend metallization wherein first conductive element 1110 and second conductive element 1120 are pinned out to pads. In next process step 1107, breaks 1137 in nanotube elements 1135 resulting from this applied electrical stimulus are visible. Within the method of FIG. 11, the applied electrical stimulus is supplied in such a way that the breaks 1137 within etched nanotube fabric 1130′ occur largely in the same location within the fabric 1130′. Within certain applications this is done by applying a relatively high (as compared with the electrical stimulus applied within the method of FIG. 9) voltage pulse across an etched nanotube fabric 1130′ comprised of nanotube elements 1135 which are substantially uniform in diameter and length. As with the previous methods, however, it should be noted that responsive to the applied electrical stimulus, any individual nanotube element 1135 may exhibit multiple breaks, a single break, or no breaks at all.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within etched nanotube fabric 1130′. As discussed previously, these break-type switching sites will provide uniformity in switching resistance from device to device as well as lower switching energy being required to adjust etched nanotube fabric 1130′ from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites within the nanotube fabric of a two-terminal nanotube switching device create uniform device-to-device performance, which is highly desirable in certain applications.

FIG. 12 is a process flow diagram illustrating a fourth method of forming a two-terminal nanotube switching device with a plurality of break-type switching sites according to the methods of the present disclosure. This fourth method uses a mixture of relatively long and relatively short nanotube elements 1235 and results in a plurality of breaks 1237 distributed across etched nanotube fabric 1230′. In a first process step 1201, a dielectric substrate layer 1250 is provided. This dielectric substrate layer 1250 can be formed from a variety of dielectric materials including, but not limited to, silicon, silicon rich oxide (SRO), or aluminum oxide. In a next process step 1202, a nanotube fabric 1230 is formed over dielectric substrate layer 1250. Nanotube fabric 1230 is comprised of nanotube elements 1235 which vary in length. Some of these nanotube elements 1235 are relatively long compared to the width of the device, while some nanotube elements 1235 are relatively short as compared to the width of the device. Nanotube fabric 1230 is preferably formed from a spin-coating operation of purified, functionalized nanotubes suspended in an application solution, as discussed in detail above and in the incorporated references. However, within certain applications, nanotube fabric 1230 could also be formed via a dip-coating operation or a spray-coating operation.

In a next process step 1203 a protective coating layer 1260 is formed over nanotube fabric layer 1230. Protective coating layer 1260 is formed from suitable dielectric protective material such as, but not limited to, silicon nitride. In a next process step 1204, nanotube fabric layer 1230 and protective coating layer 1260 are etched to form etched nanotube fabric layer 1230′ covered by etched protective layer 1260′. These two etched material layers 1230′ and 1260′ are etched back to realize a nanotube fabric that conforms to the desired geometric dimensions of the two-terminal nanotube switching device, with nanotube fabric sidewalls formed on each side of etched nanotube fabric 1230′. The etching process may be performed using an isotropic etch, for example an oxygen plasma etch. Methods for etching nanotube fabrics are discussed further in the incorporated references (for example, within U.S. Patent Publication 2021/0399219).

Within the method of FIG. 12, etched nanotube fabric 1230′ is comprised of a mixture of nanotube elements 1235 that vary in length. As with the method of FIG. 9, some nanotube elements 1235 are relatively long compared to the width of the etched nanotube fabric 1230′. That is, after the etching operation of process step 1204, many of these nanotubes 1235 have lengths equal to (and span the entirety of) the width of the etched nanotube fabric 1230′. Additionally, as within the method of FIG. 10, some nanotube elements 1235 are relatively short compared to the width of the device. As a result, etched nanotube fabric 1230′ includes some nanotube elements 1235 that span the entire width of etched nanotube fabric 1230′ from sidewall to sidewall and others nanotube elements 1235 that do not span the entire width of the etched nanotube fabric 1230′ and thus provide a plurality of end-to-end, sidewall-to-sidewall, and end-to-sidewall switching sites (as discussed in detail above with respect to FIGS. 5 and 6A-6C) being present in etched nanotube fabric 1230′.

In a next process step 1205, a first conductive element 1210 and a second conductive element 1220 are formed at opposite ends of etched nanotube fabric 1230′ such that etched nanotube fabric layer 1230′ provides an adjustable conductive path between first conductive element 1210 and second conductive element 1220. First conductive element 1210 and second conductive element 1220 are formed from a conductive material such as, but not limited to, Al, TiN, TaN, W, Ru, RuN, or RuO. Referring back to the exemplary device structure of FIG. 1C (discussed in detail above), etched nanotube fabric 1230′ is analogous to nanotube fabric 130c in FIG. 1C, first conductive element 1210 is analogous to first conductive terminal 110c in FIG. 1C, and second conductive element 1220 is analogous to second conductive terminal 120c in FIG. 1C. In this way, the basic structure of a two-terminal switching device has been formed.

In next process step 1206, a driver 1280 is used to apply an electrical stimulus across first conductive element 1210 and second conductive element 1220. This applied electrical stimulus drives a voltage, V_{BB}, across, and a current, I_{BB}, through etched nanotube fabric 1230′ as each end of etched nanotube fabric 1230′ is in electrical contact with one of conductive elements 1210 and 1220, each against a different sidewall of etched nanotube fabric 1230′. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1235 within etched nanotube fabric 1230′. Depending on the needs of the specific application, the application of this electrical stimulus can be performed through backend metallization wherein first conductive element 1210 and second conductive element 1220 are pinned out to pads. In next process step 1207, breaks 1237 in nanotube elements 1235 resulting from this applied electrical stimulus are visible. These breaks 1237 are distributed across etched nanotube fabric 1230′ and are present within both short and long nanotube elements 1235. As with the previous methods, it should be noted that responsive to the applied electrical stimulus, any individual nanotube element 1235 may exhibit multiple breaks, a single break, or no breaks at all.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within etched nanotube fabric 1230′. As discussed previously, these break-type switching sites will provide uniformity in switching resistance from device to device as well as lower switching energy being required to adjust etched nanotube fabric 1230′ from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites with the nanotube fabric of a two-terminal nanotube switching device create uniform device-to-device performance, which is highly desirable in certain applications.

FIG. 13 is a process flow diagram illustrating a fifth method of forming a two-terminal nanotube switching device with a plurality of break-type switching sites according to the methods of the present disclosure. This fifth method realizes a vertically oriented two-terminal nanotube switching device analogous to the device structure shown in FIG. 1A and discussed in detail above. In a first process step 1301, a dielectric substrate layer 1350 is provided. This dielectric substrate layer 1350 can be formed from a variety of dielectric materials including, but not limited to, silicon, silicon rich oxide (SRO), or aluminum oxide.

In a next process step 1302, a first conductive element 1310 is formed over dielectric substrate layer 1350. In a next process step 1303, a nanotube fabric 1330 comprised of a plurality of nanotube elements 1335 is formed over first conductive layer 1310. Nanotube fabric 1330 is preferably formed from a spin-coating operation of purified, functionalized nanotubes suspended in an application solution, as discussed in detail above and in the incorporated references. However, within certain applications, nanotube fabric 1330 could also be formed via a dip-coating operation or a spray-coating operation. In a next process step 1304, a second conductive layer 1320 is formed over nanotube fabric 1330 such that nanotube fabric layer 1330 provides an adjustable conductive path between first conductive layer 1310 and second conductive layer 1320. First conductive layer 1310 and second conductive layer 1320 are formed from a conductive material such as, but not limited to, Al, TiN, TaN, W, Ru, RuN, or RuO.

In a next process step 1305, first conductive layer 1310, nanotube fabric layer 1330 and second conductive layer 1320 are etched to form etched first conductive layer 1310′, etched nanotube fabric layer 1330′, and etched second conductive layer 1320′. These three etched material layers 1320′, 1330′ and 1320′ are etched back to realize a two-terminal nanotube switching device that conforms to preselected geometric dimensions of the two-terminal nanotube switching device. The etching process may be performed using an isotropic etch, for example an oxygen plasma etch. Methods for etching nanotube fabrics are discussed further in the incorporated references (for example, within U.S. Patent Publication 2021/0399219). Referring back to the exemplary device structure of FIG. 1A (discussed in detail above), etched nanotube fabric 1330′ is analogous to nanotube fabric 130a in FIG. 1A, etched first conductive layer 1310′ is analogous to first conductive terminal 110a in FIG. 1A, and etched second conductive layer 1320′ is analogous to second conductive terminal 120a in FIG. 1A. In this way, the basic structure of a two-terminal switching device has been formed. In a next process step 1306 a protective coating layer 1360 is formed over etched first conductive layer 1310′, etched nanotube fabric layer 1330′, and etched second conductive layer 1320′. Protective coating layer 1360 is formed from suitable dielectric protective material such as, but not limited to, silicon nitride.

Within the method of FIG. 13, the conductive path between etched first conductive layer 1310′ and etched second conductive layer 1320′ provided by etched nanotube fabric layer 1330′ runs vertically through etched nanotube fabric layer 1330′. As such, this conductive path is, initially, realized through a plurality of end-to-end, sidewall-to-sidewall, and end-to-sidewall switching sites (as discussed in detail above with respect to FIGS. 5 and 6A-6C) being present in nanotube fabric 1330 as deposited.

In next process step 1307, a driver 1380 is used to apply an electrical stimulus across etched first conductive layer 1310′ and etched second conductive layer 1320′. This applied electrical stimulus drives a voltage, V_{BB}, across, and a current, I_{BB}, through etched nanotube fabric 1330′ as the bottom surface of etched nanotube fabric 1330′ is in electrical contact with etched first conductive layer 1310′ and the top surface of etched nanotube fabric 1330′ is in electrical contact with etched second conductive layer 1320′. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1335 within etched nanotube fabric 1330′. Depending on the needs of the specific application, the application of this electrical stimulus can be performed through backend metallization wherein etched first conductive layer 1310′ and etched second conductive layer 1320′ are pinned out to pads. In next process step 1308, breaks 1337 in nanotube elements 1335 resulting from this applied electrical stimulus are visible. It should be noted that responsive to the applied electrical stimulus, an individual nanotube element 1335 may exhibit multiple breaks or a single break. Additionally, an individual nanotube element 1335 may exhibit no breaks at all. That is, the methods of the present disclosure do not require that every nanotube element 1335 exhibit the same number of breaks or even breaks of equal size. Instead, the methods of the present disclosure provide that the applied electrical stimulus introduces a plurality of breaks 1337 distributed through the etched nanotube fabric 1330′ as a whole.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within etched nanotube fabric 1330′ over the other types of switching sites originally present in etched nanotube fabric 1330′ when initially formed. As discussed previously, these break-type switching sites will provide uniformity in switching resistance from device to device as well as lower switching energy being required to adjust etched nanotube fabric 1330′ from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites within the nanotube fabric of a two-terminal nanotube switching device create uniform device-to-device performance, which is highly desirable in certain applications.

FIG. 14 is a process flow diagram illustrating a sixth method of forming a two-terminal nanotube switching device with a plurality of break-type switching sites according to the methods of the present disclosure. This sixth method realizes a horizontally oriented two-terminal nanotube switching device with contacts below the nanotube fabric analogous to the device structure shown in FIG. 1B and discussed in detail above. In a first process step 1401, a dielectric substrate layer 1450 is provided. This dielectric substrate layer 1450 can be formed from a variety of dielectric materials including, but not limited to, silicon, silicon rich oxide (SRO), or aluminum oxide.

In a next process step 1402, a first conductive element 1410 and a second conductive element 1420 are formed within dielectric substrate layer 1450. First conductive element 1410 and second conductive element 1420 are formed from a conductive material such as, but not limited to, Al, TiN, TaN, W, Ru, RuN, or RuO. In a next process step 1403, a nanotube fabric 1430 comprised of a plurality of nanotube elements 1435 is formed over first conductive layer 1410. Nanotube fabric 1430 is preferably formed from a spin-coating operation of purified, functionalized nanotubes suspended in an application solution, as discussed in detail above and in the incorporated references. However, within certain applications, nanotube fabric 1430 could also be formed via a dip-coating operation or a spray-coating operation. Referring back to the exemplary device structure of FIG. 1B (discussed in detail above), nanotube fabric 1430 is analogous to nanotube fabric 130b in FIG. 1B, first conductive element 1410 is analogous to first conductive terminal 110b in FIG. 1B, and second conductive element 1420 is analogous to second conductive terminal 120b in FIG. 1B. In this way, the basic structure of a two-terminal switching device has been formed. In a next process step 1404 a protective coating layer 1460 is formed over nanotube fabric 1430. Protective coating layer 1460 is formed from suitable dielectric protective material such as, but not limited to, silicon nitride.

In next process step 1405, a driver 1480 is used to apply an electrical stimulus across first conductive element 1410 and second conductive element 1420. This applied electrical stimulus drives a voltage, V_{BB}, across, and a current, I_{BB}, through nanotube fabric 1430 as one end of the bottom surface of nanotube fabric 1430 is in electrical contact with first conductive element 1410 and the other end of the bottom surface of nanotube fabric 1430 is in electrical contact with second conductive element 1420. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1435 within nanotube fabric 1430. Depending on the needs of the specific application, the application of this electrical stimulus can be performed through backend metallization wherein first conductive element 1410 and second conductive element 1420 are pinned out to pads. In next process step 1406, breaks 1437 in nanotube elements 1435 resulting from this applied electrical stimulus are visible. It should be noted that responsive to the applied electrical stimulus, an individual nanotube element 1435 may exhibit multiple breaks or a single break. Additionally, an individual nanotube element 1435 may exhibit no breaks at all. That is, the methods of the present disclosure do not require that every nanotube element 1435 exhibit the same number of breaks or even breaks of equal size. Instead, the methods of the present disclosure provide that the applied electrical stimulus introduces a plurality of breaks 1437 distributed through the nanotube fabric 1430 as a whole.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within nanotube fabric 1430 over the other types of switching sites originally present in nanotube fabric 1430 when initially formed. As discussed previously, these break-type switching sites will provide uniformity in switching resistance from device to device as well as lower switching energy being required to adjust nanotube fabric 1430 from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites within the nanotube fabric of a two-terminal nanotube switching device create uniform device-to-device performance, which is highly desirable in certain applications.

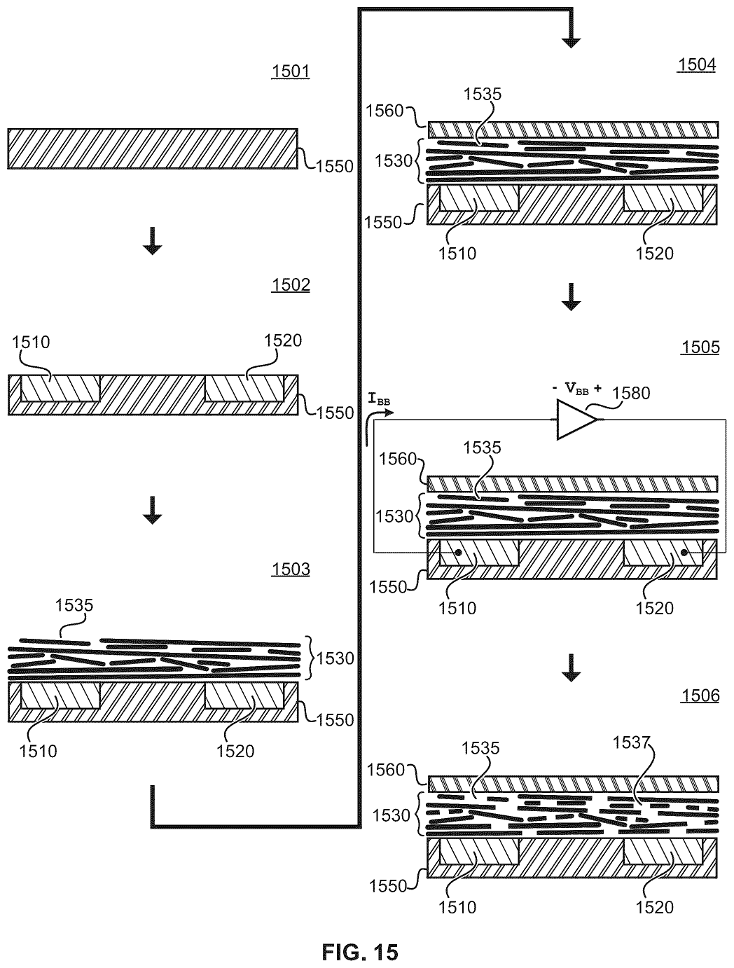

FIG. 15 is a process flow diagram illustrating a seventh method of forming a two-terminal nanotube switching device with a plurality of break-type switching sites according to the methods of the present disclosure. This seventh method uses a mixture of relatively long and relatively short nanotube elements 1535 and realizes a horizontally oriented two-terminal nanotube switching device with contacts below the nanotube fabric analogous to the device structure shown in FIG. 1B and discussed in detail above. In a first process step 1501, a dielectric substrate layer 1550 is provided. This dielectric substrate layer 1550 can be formed from a variety of dielectric materials including, but not limited to, silicon, silicon rich oxide (SRO), or aluminum oxide.

In a next process step 1502, a first conductive element 1510 and a second conductive element 1520 are formed within dielectric substrate layer 1550. First conductive element 1510 and second conductive element 1520 are formed from a conductive material such as, but not limited to, Al, TiN, TaN, W, Ru, RuN, or RuO. In a next process step 1503, a nanotube fabric 1530 comprised of a plurality of nanotube elements 1535 is formed over first conductive layer 1510. Nanotube fabric 1530 is preferably formed from a spin-coating operation of purified, functionalized nanotubes suspended in an application solution, as discussed in detail above and in the incorporated references. However, within certain applications, nanotube fabric 1530 could also be formed via a dip-coating operation or a spray-coating operation. Referring back to the exemplary device structure of FIG. 1B (discussed in detail above), nanotube fabric 1530 is analogous to nanotube fabric 130b in FIG. 1B, first conductive element 1510 is analogous to first conductive terminal 110b in FIG. 1B, and second conductive element 1520 is analogous to second conductive terminal 120b in FIG. 1B. In this way, the basic structure of a two-terminal switching device has been formed. In a next process step 1504 a protective coating layer 1560 is formed over nanotube fabric 1530. Protective coating layer 1560 is formed from suitable dielectric protective material such as, but not limited to, silicon nitride.

Within the method of FIG. 15, nanotube fabric 1530 is comprised of a mixture of nanotube elements 1535 that vary in length. As with the method of FIG. 9, some nanotube elements 1535 are relatively long compared to the width of the nanotube fabric 1530. That is, after the etching operation of process step 1504, many of these nanotubes 1535 have lengths equal to (and span the entirety of) the width of the etched nanotube fabric 1530. Additionally, as within the method of FIG. 10, some nanotube elements 1535 are relatively short compared to the width of the device. As a result, nanotube fabric 1530 includes some nanotube elements 1535 that span the entire width of nanotube fabric 1530 from sidewall to sidewall and others nanotube elements 1535 that do not span the entire width of the nanotube fabric 1530 and thus provide a plurality of end-to-end, sidewall-to-sidewall, and end-to-sidewall switching sites (as discussed in detail above with respect to FIGS. 5 and 6A-6C) being present in nanotube fabric 1530.

In next process step 1505, a driver 1580 is used to apply an electrical stimulus across first conductive element 1510 and second conductive element 1520. This applied electrical stimulus drives a voltage, V_{BB}, across, and a current, I_{BB}, through nanotube fabric 1530 as one end of the bottom surface of nanotube fabric 1530 is in electrical contact with first conductive element 1510 and the other end of the bottom surface of nanotube fabric 1530 is in electrical contact with second conductive element 1520. This applied electrical stimulus can be a single voltage pulse for a set duration or a series of electrical pulses. As discussed above with respect to FIG. 8, according to the methods of the present disclosure this applied electrical stimulus is selected to provide a voltage and current (or a series of repeatedly applied voltages and currents) sufficient to create a plurality of breaks within the nanotube elements 1535 within nanotube fabric 1530. Depending on the needs of the specific application, the application of this electrical stimulus can be performed through backend metallization wherein first conductive element 1510 and second conductive element 1520 are pinned out to pads. In next process step 1506, breaks 1537 in nanotube elements 1535 resulting from this applied electrical stimulus are visible. These breaks 1537 are distributed across nanotube fabric 1530 and are present within both short and long nanotube elements 1535. It should be noted that responsive to the applied electrical stimulus, an individual nanotube element 1535 may exhibit multiple breaks or a single break. Additionally, an individual nanotube element 1535 may exhibit no breaks at all. That is, the methods of the present disclosure do not require that every nanotube element 1535 exhibit the same number of breaks or even breaks of equal size. Instead, the methods of the present disclosure provide that the applied electrical stimulus introduces a plurality of breaks 1537 distributed through the nanotube fabric 1530 as a whole.

In this way, by controlling the parameters of the applied electrical stimulus, a plurality of break-type switching sites (as shown and described with respect to FIG. 8 above) can be introduced across the fabric. In certain applications, the applied electrical stimulus can be selected such that the number of break-type switching sites created is high enough that these sites dominate the switching function within nanotube fabric 1530 over the other types of switching sites originally present in nanotube fabric 1530 when initially formed. As discussed previously, these break-type switching sites will provide uniformity in switching resistance from device to device as well as lower switching energy being required to adjust nanotube fabric 1530 from one nonvolatile resistive state to another. In this way, a two-terminal nanotube switching device is formed via the methods of the present disclosure that is comprised of a nanotube fabric exhibiting a plurality of break-type switching sites. As discussed in detail above, these break-type switching sites within the nanotube fabric of a two-terminal nanotube switching device create uniform device-to-device performance, which is highly desirable in certain applications.

Although the present disclosure has been described in relation to particular embodiments thereof, many other variations and modifications and other uses will become apparent to those skilled in the art. It is preferred, therefore, that the present disclosure not be limited by the specific disclosure herein.

What is claimed is:

1. A resistive change element comprising:
a nanotube fabric comprising a plurality of nanotubes, wherein said plurality of nanotubes are configured to form a plurality of break-type switching sites;
a first conductive terminal in electrical communication with said nanotube fabric;
a second conductive terminal in electrical communication with said nanotube fabric; and
wherein said resistive change element is adjustable between a low resistive state and a high resistive state, wherein a resistance of said low resistive state is less than a resistance of said high resistive state, and wherein a difference between said resistance of said low resistive state and said resistance of said high resistive state is dominated by movement of nanotubes at said plurality of break-type switching sites in response to an electrical stimulus.

2. The resistive change element of claim 1, wherein said nanotube fabric has a first sidewall and a second sidewall, wherein said first conductive terminal is in electrical communication with said first sidewall, and wherein said second conductive terminal is in electrical communication with said second sidewall.

3. The resistive change element of claim 1, wherein said first conductive terminal is a top conductive terminal, wherein said second conductive terminal is a bottom conductive terminal, and wherein said nanotube fabric is between said top conductive terminal and said bottom conductive terminal.

4. The resistive change element of claim 1, wherein said first conductive terminal is a first bottom conductive terminal, wherein said second conductive terminal is a second bottom conductive terminal, and wherein said nanotube fabric is over said first bottom conductive terminal and said second bottom conductive terminal.

5. The resistive change element of claim 1, further comprising a protective layer over said nanotube fabric.

6. The resistive change element of claim 1, wherein said plurality of nanotubes is a plurality of carbon nanotubes.

7. The resistive change element of claim 1, wherein said low resistive state is a nonvolatile low resistive state and said high resistive state is a nonvolatile high resistive state.

8. A resistive change element comprising:
a nanotube fabric comprising a plurality of nanotubes, wherein said plurality of nanotubes are configured to form a plurality of switching sites from application of an electrical stimulus to said nanotube fabric;
a first conductive terminal in electrical communication with said nanotube fabric;
a second conductive terminal in electrical communication with said nanotube fabric; and
wherein said resistive change element is adjustable between a low resistive state and a high resistive state, wherein a resistance of said low resistive state is less than a resistance of said high resistive state, and wherein a difference between said resistance of said low resistive state and said resistance of said high resistive state is dominated by movement of nanotubes at said plurality of break-type switching sites in response to a programming stimulus.

9. The resistive change element of claim 8, wherein said nanotube fabric has a first sidewall and a second sidewall, wherein said first conductive terminal is in electrical communication with said first sidewall, and wherein said second conductive terminal is in electrical communication with said second sidewall.

10. The resistive change element of claim 8, wherein said first conductive terminal is a top conductive terminal, wherein said second conductive terminal is a bottom conductive terminal, and wherein said nanotube fabric is between said top conductive terminal and said bottom conductive terminal.

11. The resistive change element of claim 8, wherein said first conductive terminal is a first bottom conductive terminal, wherein said second conductive terminal is a second bottom conductive terminal, and wherein said nanotube fabric is over said first bottom conductive terminal and said second bottom conductive terminal.

12. The resistive change element of claim 8, further comprising a protective layer over said nanotube fabric.

13. The resistive change element of claim 8, wherein said plurality of nanotubes is a plurality of carbon nanotubes.

14. The resistive change element of claim 8, wherein said low resistive state is a nonvolatile low resistive state and said high resistive state is a nonvolatile high resistive state.
